(19) United States
(12) Patent Application Publication
(10) Pub. No.: US 2023/0272537 A1
(43) Pub. Date: Aug. 31, 2023

(54) FUNCTIONAL FILM AND PRODUCTION METHOD OF FUNCTIONAL FILM

(71) Applicant: KONICA MINOLTA, INC., Tokyo (JP)

(72) Inventor: Kazunari TADA, Tokyo (JP)

(73) Assignee: KONICA MINOLTA, INC., Tokyo (JP)

(21) Appl. No.: 18/173,376

(22) Filed: Feb. 23, 2023

(30) Foreign Application Priority Data
Feb. 25, 2022 (JP) 2022-027859

(51) Int. Cl. C23C 28/00

(52) U.S. Cl. CPC C23C 28/345

(57) ABSTRACT

A functional film that has a hydrophilic property or an antifog property and that is formed on a base material includes a fluorine-containing layer that contains fluorine.

### REFERENCE TO RELATED APPLICATIONS

The entire disclosure of Japanese Patent Application No. 2022-027859, filed on Feb. 25, 2022, including description, claims, drawings and abstract is incorporated herein by reference in its entirety.

### TECHNICAL FIELD

The present invention relates to a functional film and a production method of the functional film. In particular, the present invention relates to a functional film and the like that does not lose hydrophilic properties even when the base material does not include a hydrophilic component.

### DESCRIPTION OF THE RELATED ART

Conventional hydrophilic films and antifog films are weak against high temperature and high humidity, and have large contact angles due to water containing alkali components, oil, and other contaminants.

The above problem has been solved, for example, by inclusion of a components (for example, an alkali metal) related to hydrophilic properties in the film (see, for example, JP 2013-203774 A). However, even when the hydrophilic film has such properties, when the base material does not have the components responsible for hydrophilic properties, the hydrophilic component eventually diffuses into the base material and disappears, resulting in deterioration of hydrophilic properties and antifog properties.

### SUMMARY OF THE INVENTION

The present invention was made in view of the above problems and circumstances, and its purpose is to provide a functional film and a production method of the functional film that does not lose its properties even when the base material does not include hydrophilic components.

In the process of examining the causes of the above problems, the inventor of the present invention found that a functional film that does not lose its properties even when the base material does not include hydrophilic components can be provided by including a fluorine-containing layer containing fluorine in the film, and thus arrived at the present invention.

In other words, the above problems related to the present invention are solved by the following means.

To achieve at least one of the abovementioned objects, according to an aspect of the present invention, a functional film that has a hydrophilic property or an antifog property and that is formed on a base material includes a fluorine-containing layer that contains fluorine.

According to another aspect of the present invention, a production method of the functional film according to claim 1 includes forming of the fluorine-containing layer on the base material.

### BRIEF DESCRIPTION OF THE DRAWINGS

The advantages and features provided by one or more embodiments of the invention will become more fully understood from the detailed description given hereinafter and the appended drawings which are given by way of illustration only, and thus are not intended as a definition of the limits of the present invention, and wherein:

FIG. 1 is a cross-sectional schematic diagram showing an example of a basic structure of a functional film of the present invention;

FIG. 2A is a process diagram showing an example of a production method of the functional film of the present invention;

FIG. 2B is a process diagram showing an example of a production method of the functional film of the present invention;

FIG. 2C is a process diagram showing an example of a production method of the functional film of the present invention;

FIG. 3A is a cross-sectional schematic diagram showing a structure of Functional Film 1 in Example 1;

FIG. 3B is a cross-sectional schematic diagram showing a structure of Functional Film 1 in Example 1;

FIG. 3C is a cross-sectional schematic diagram showing a structure of Functional Film 1 in Example 1;

FIG. 3D is a cross-sectional schematic diagram showing a structure of Functional Film 1 in Example 1;

FIG. 3E is a cross-sectional schematic diagram showing a structure of Functional Film 1 in Example 1;

FIG. 3F is a cross-sectional schematic diagram showing a structure of Functional Film 1 in Example 1;

FIG. 4A is a cross-sectional schematic diagram showing a structure of Functional Film 2 in Example 2;

FIG. 4B is a cross-sectional schematic diagram showing a structure of Functional Film 2 in Example 2;

FIG. 4C is a cross-sectional schematic diagram showing a structure of Functional Film 2 in Example 2;

FIG. 5A is a cross-sectional schematic diagram showing a structure of Functional Film 3 in Example 3;

FIG. 5B is a cross-sectional schematic diagram showing a structure of Functional Film 3 in Example 3;

FIG. 5C is a cross-sectional schematic diagram showing a structure of Functional Film 3 in Example 3;

FIG. 5D is a cross-sectional schematic diagram showing a structure of Functional Film 3 in Example 3;

FIG. 6A is a cross-sectional schematic diagram showing a structure of Functional Film 4 in Example 4;

FIG. 6B is a cross-sectional schematic diagram showing a structure of Functional Film 4 in Example 4;

FIG. 6C is a cross-sectional schematic diagram showing a structure of Functional Film 4 in Example 4;

FIG. 7A is a cross-sectional schematic diagram showing a structure of Functional Film 5 in Example 5;

FIG. 7B is a cross-sectional schematic diagram showing a structure of Functional Film 5 in Example 5;

FIG. 7C is a cross-sectional schematic diagram showing a structure of Functional Film 5 in Example 5;

FIG. 7D is a cross-sectional schematic diagram showing a structure of Functional Film 5 in Example 5;

FIG. 8A is a cross-sectional schematic diagram showing a structure of Functional Film 6 in Example 6;

FIG. 8B is a cross-sectional schematic diagram showing a structure of Functional Film 6 in Example 6;

FIG. 8C is a cross-sectional schematic diagram showing a structure of Functional Film 6 in Example 6;

FIG. 8D is a cross-sectional schematic diagram showing a structure of Functional Film 6 in Example 6;

FIG. 8E is a cross-sectional schematic diagram showing a structure of Functional Film 6 in Example 6;

FIG. 8F is a cross-sectional schematic diagram showing a structure of Functional Film 6 in Example 6;

FIG. 9A is a cross-sectional schematic diagram showing a structure of Functional Film 7 in Example 7;

FIG. 9B is a cross-sectional schematic diagram showing a structure of Functional Film 7 in Example 7;

FIG. 9C is a cross-sectional schematic diagram showing a structure of Functional Film 7 in Example 7;

FIG. 10 is a cross-sectional schematic diagram showing a structure of Functional Film 19 in Comparative Example 1;

FIG. 11 is a cross-sectional schematic diagram showing a structure of Functional Film 20 in Comparative Example 2;

FIG. 12A is a diagram showing a result of composition analysis of an uppermost layer of Functional Film 1 in Example 1; and

FIG. 12B is a diagram showing a result of composition analysis of an uppermost layer of Functional Film 1 in Example 1.

### DETAILED DESCRIPTION

Hereinafter, one or more embodiments of the present invention will be described with reference to the drawings. However, the scope of the invention is not limited to the disclosed embodiments.

By the above means of the present invention, it is possible to provide a functional film and a production method of the functional film that lose its properties even when the base material does not include a hydrophilic component.

The expression mechanism of the effect or action mechanism of the present invention is not clear, but is inferred as follows.

A material that prevents diffusion of a hydrophilic component provided between the base material and the functional film, that is, a fluorine-containing layer, can prevent the outflow of the hydrophilic component. Specifically, a layer that contains an alkali metal or an alkaline earth metal as a component responsible for hydrophilic and antifog properties is formed. Then, as a component that prevents the diffusion of the above component, a layer that contains fluorine is included as part of the functional film or is alternately accumulated. This prevents the alkali metal or the alkaline earth metal from disappearing. As a result, the high temperature and high humidity properties regarding the hydrophilic properties and antifog properties can be improved even when the base material does not contain a hydrophilic or antifog component.

The functional film of the present invention is a hydrophilic or antifog functional film provided on a base material, and is characterized by including a fluorine-containing layer that contains fluorine.

This feature is a technical feature common to or corresponding to each of the following embodiments.

As an embodiment of the present invention, inclusion of a metal-containing layer that contains an alkali metal or an alkaline earth metal is preferred in terms of excellent hydrophilic or antifog properties.

It is preferred that the metal-containing layer contains sodium, in that it improves the high temperature and high humidity resistance of the hydrophilic properties.

It is preferred that the fluorine-containing layer further contains aluminum, in that it improves the high temperature and high humidity resistance.

It is preferred that the functional film of the present invention further includes a layer containing SiO₂ in that it enhances the hydrophilic properties and optical properties.

It is preferred that a part of the fluorine-containing layer contains at least one of or constituent elements of the at least one of AlF₃, Al₂O₃, CaF₂, NaF, Na₅Al₃F₁₄, and Na₃AlF₆, in that it improves the high temperature and high humidity resistance.

When the base material contains an alkali metal or an alkaline earth metal and the content of the alkali metal or the alkaline earth metal in the base material is 3% by mass or less, the effect of the present invention can be particularly effectively achieved.

The functional film preferably has a fine uneven structure on its surface, and the mutual positional relationship and shape of a plurality of bumps and dents of the fine uneven structure preferably are random and have no regularity in terms of identity or periodicity so as not to generate diffracted light. The presence of fine unevenness and the lack of diffracted light can provide the effect of improved visibility and good functionality as an optical component. Furthermore, the functions of the functional film of the present invention, such as hydrophilic properties or antifog properties, can be enhanced.

In the fine uneven structure, the arithmetic average roughness Ra of the bumps is preferably in the range of 0.5 to 50 nm, the maximum height of the bumps is preferably in the range of 10 to 300 nm, and the average diameter of the bumps is preferably in the range of 10 to 500 nm, in order that both rub resistance and the properties of the functional film can be obtained.

The fine uneven structure preferably has a gap between bumps and dents adjacent to each other that is large enough to allow the active chemical species generated by the photocatalyst reaction to pass through the gap, in terms of keeping the surface clean, increasing the surface area, and enhancing the hydrophilic properties and antifog properties.

A photocatalytic layer is preferably provided between the base material and the fine uneven structure so as to express photocatalytic effects.

The contact angle of the surface of the functional film after 100 hours of storage in a 85° C. and 85% RH environment is preferably 30° or less in terms of enhancing the hydrophilic properties under high temperature and high humidity environment.

The contact angle of the surface of the functional film after a test of rubbing 100 times back and forth with a load of 0.1 kg with a scourer (a palm fiber scourer called Kamenoko Tawashi in Japan and made of palm fiber) is preferably 30° or less in terms of improving the rub resistance and the hydrophilic properties.

The contact angle of the surface of the functional film after 100 hours of storage in a 85° C. and dry environment is preferably 30° or less in terms of enhancing the hydrophilic properties under a high temperature and high humidity environment.

In addition, no scratches preferably appear on the surface of the functional film after a test of rubbing 100 times back and forth with a load of 0.1 kg with the scourer (Kamenoko Tawashi) in terms of improving the rub resistance.

The production method of the functional film of the present invention is characterized by the process of forming a fluorine-containing layer containing fluorine on the base material. This makes it possible to produce a functional film whose characteristics are not deteriorated even when the base material does not contain a hydrophilic component.

The process of forming the metal-containing layer containing an alkali metal or an alkaline earth metal by a dry process is preferably included in order that a functional film having the excellent hydrophilic or antifog properties can be made.

The process of forming the metal-containing layer preferably includes an exposing process to an environment containing moisture, in that the metal-containing layer can be easily formed in the form of uniformly distributed particles and that the properties of the resulting functional film are excellent.

The uneven structure is preferably formed in the formation process of the metal-containing layer in that the resistance to high temperature and high humidity can be improved.

After the process of forming the metal-containing layer, the production method preferably includes the process of forming a layer containing SiO₂ on the metal-containing layer by the dry process in that the functional film having the fine uneven structure can be easily produced.

In the process of forming the fluorine-containing layer, the fluorine-containing layer preferably includes granular layers that contain grains of less than 10 nm and alternately stacked with layers other than the fluorine-containing layers, such that the fine uneven structure is formed on the surface, in that the resistance to high temperature and high humidity can be improved.

In the process of forming the fluorine-containing layer, it is preferred to form the fluorine-containing layer at a temperature of 200° C. or higher, because the higher the temperature, the more clear the unevenness becomes.

In the process of forming the functional film, it is preferred to form all layers by the dry process because it improves the adhesion and the rub resistance and allows easy production of the fine uneven structure and porous structure.

In addition, at least one layer may be formed by a wet process in the process of forming the functional film.

Hereinafter, the invention, its components, and the embodiments and modes of carrying out the present invention will be described. The term “to” as used in this application means that the values listed immediately before and after it are respectively included as the lower and upper limits.

[Summary of Functional Film of Present Invention]

The functional film of the present invention is a hydrophilic or antifog functional film provided on a base material, and includes a fluorine-containing layer that contains fluorine. The functional film preferably includes a metal-containing layer containing an alkali metal or an alkaline earth metal, and furthermore, the functional film preferably includes a layer containing SiO₂ (hereinafter also referred to as “SiO₂ layer”). Also, the functional film preferably includes a reflectance adjustment layer and a photocatalytic layer.

In the present invention, the term “hydrophilic properties” means that a contact angle B1 of a functional film is greater than 10° and 30° or less. The contact angle B1, which is a static contact angle of a functional film that has been left in a high temperature and dry environment for 100 hours, is measured 5 seconds after a drop of 10 μL of pure water onto the surface using a contact angle measurement device G-1 (manufactured by ERMA Inc.) at 23° C. and 50% RH.

In the present invention, the term “antifog properties” means that the above contact angle B1 is 10° or less.

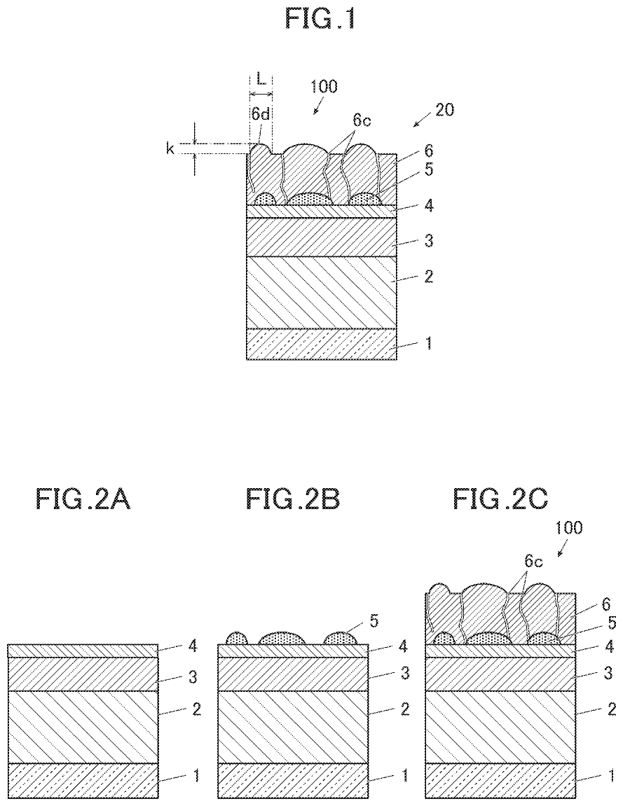

FIG. 1 is a cross-sectional schematic diagram showing an example of the basic structure of the functional film of the present invention. FIG. 1 merely shows an example of the functional film of the present invention and does not limit the layer structure.

As shown in FIG. 1, on the base material 1, a reflectance adjustment layer 2, a photocatalytic layer 3, a fluorine-containing layer 4, a metal-containing layer 5, and a coating film 6 or a coating layer 6 are stacked in this order. The coating film 6 or the coating layer 6 preferably includes the SiO₂ layer as part of its structure. The metal-containing layer is not limited to be at the portion illustrated as the reference numeral 5 in FIG. 1, but may be included as a part of the coating film or the coating layer shown as the reference numeral 6. Alternatively, the metal-containing layer may have other configurations as described below.

The following is an explanation of each layer composition.

<Fluorine-Containing Layer>

The fluorine-containing layer is a layer that contains at least fluorine.

In addition to fluorine, the fluorine-containing layer may contain aluminum, calcium, sodium, chlorine, magnesium, and the like. In particular, fluorine-containing layer preferably contains aluminum and/or sodium to improve resistance to high temperature and high humidity.

It is preferred that a part of the fluorine-containing layer contains the constituent elements of at least one of AlF₃, Al₂O₃, CaF₂, NaF, Na₅Al₃F₁₄ (thiolite), and Na₃AlF₆ (cryolite) in that the resistance to high temperature and high humidity can be improved. In particular, at least one of AlF₃, Na₅Al₃F₁₄ (thiolite), and Na₃AlF₆ (cryolite) is preferably contained.

Since fluorine is a material that prevents diffusion of hydrophilic components, it is possible to prevent the outflow of a hydrophilic component in the functional film that includes the fluorine-containing layer as a part of the functional film. Specifically, the metal-containing layer containing an alkali metal or an alkaline earth metal is provided as a component responsible for hydrophilic and antifog properties, and the fluorine-containing layer is at least partly provided as a component that prevents diffusion of the component. This prevents the alkali metal or the alkaline earth metal in the metal-containing layer from disappearing. As a result, the high temperature and high humidity properties of the hydrophilic and antifog properties can be improved even when the base material does not include the hydrophilic or antifog component.

The fluorine-containing layer is preferably formed by the dry process. Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred.

The thickness of the fluorine-containing layer is preferably in the range of 0.1 to 500 nm.

The fluorine-containing layer may also serve as the metal-containing layer (also referred to as “metal-fluorine-containing layer” in the following) as described below.

<Metal-Containing Layer>

The metal-containing layer contains an alkali metal or an alkaline earth metal. The metal-containing layer is a layer that serves as a prototype or underlying layer of the outermost surface of the functional film having the fine uneven structure, and preferably has a bump shape such as a particle shape or an island shape.

For example, during the production process of the functional film, metal particles (for example, sodium chloride crystal particles) are first formed or arranged in a particulate form on a surface of an under layer (for example, the base material or the reflectance adjustment layer) that finally serves as the underlying layer of the metal-containing layer, and then covered with the coating film or coating layer (for example, SiO₂ layer). The metal-containing layer is preferably a layer containing the metal particles so as to be recognized as a layer in the shape having the uneven structure.

There are various methods of forming or arranging metal particles in the particle shape. In one of the preferred methods, a layer that consists of a particle constituent or a particle aggregate but does not yet have a predetermined fine uneven structure is formed by the dry process as a “precursor of the metal-containing layer in the shape having the uneven structure” first, and then exposed to an atmospheric environment containing moisture. As a result, the particle constituent or the particle aggregate becomes separated and isolated particles (dots) that forms a layer having the uneven shape, that is, a layer having the fine uneven structure.

Examples of the alkali metal or the alkaline earth metal contained in the above metal-containing layer include Li (lithium), Na (sodium), K (potassium), Rb (rubidium), Cs (cesium), Fr (francium), Be (beryllium), Mg (magnesium), Ca (calcium), Sr (strontium), Ba (barium), and Ra (radium). In particular, Na (sodium) or Mg (magnesium) are preferred.

The alkali metal or the alkaline earth metal is preferably contained as a compound having a solubility of 0.5 g/100 mL or more in water at 20° C. Such compound contains moisture when exposed to air or water vapor after the dry process, such that uniformly distributed particles are easily formed in the process of forming the metal-containing layer.

Examples of the compound having a solubility of 0.5 g/100 mL or more include LiCl (solubility: 76.9 g/100 mL (20° C.)), NaCl (solubility: 35.9 g/100 mL (20° C.), MgCl₂·6H₂O (solubility: 54.3 g/100 mL (20° C.)), KCl (solubility: 34.0 g/100 mL (20° C.)), CaCl₂ (solubility: 74.5 g/100 mL (20° C.)), Na₂CO₃ (solubility: 22 g/100 mL (20° C.)), and NaF (solubility: 4.06 g/100 mL (20° C.)).

The compound is preferably an inorganic salt. At least a part of the inorganic salt preferably contains an alkali metal, in that it improves the high temperature and high humidity resistance of the hydrophilic properties.

Preferred examples of the inorganic salt that meets the above solubility range and contains an alkali metal or an alkaline earth metal include NaCl, NaF, MgCl₂·6H₂O, and the like.

The average particle diameter of the metal particles contained in the metal-containing layer is preferably in the range of 10 to 1000 nm. The average particle diameter of the particles can be measured using an electron microscope (S-4800, manufactured by Hitachi High-Tech Corporation) or an atomic force microscope (L-Trace SII, manufactured by NanoTechnology Corporation).

The metal-containing layer is preferably formed by the dry process, in that uniformly distributed fine uneven structures and porous structures can be easily produced.

Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred. In particular, resistance heating vacuum vapor deposition is preferred.

The thickness of the metal-containing layer formed as described above is preferably in the range of 0.1 to 100 nm.

The functional film preferably includes at least one metal-containing layer. More preferably, the particle containing layer is provided at least adjacent to a lower surface of the SiO₂ layer.

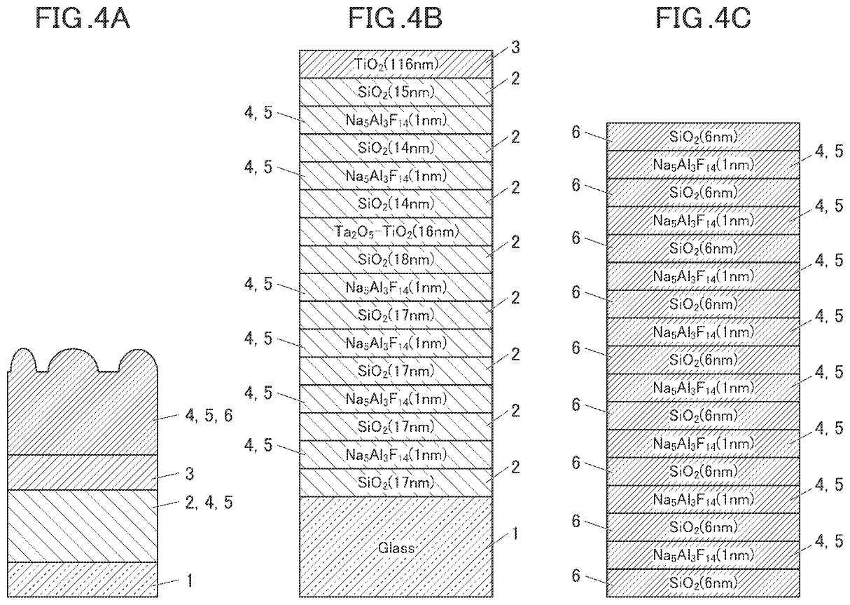

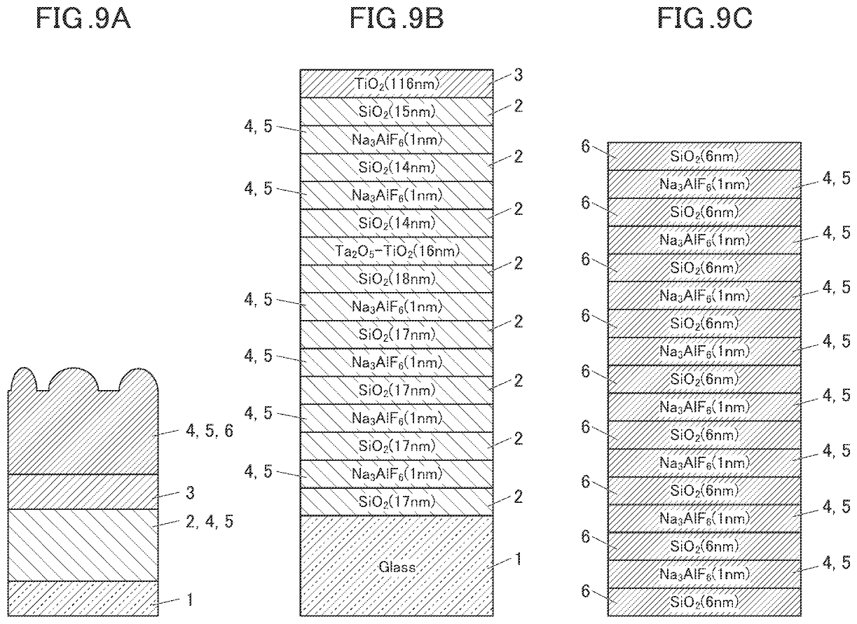

The metal-containing layer may be provided not only on the fluorine-containing layer 4 as shown in FIG. 1, but also between a plurality of stacked reflectance adjustment layers. Specifically, Na₅Al₃F₁₄ layers (metal-containing layers) may be provided between the SiO₂ layers (first low refractive index layers) as in FIG. 4B, or Na₅Al₃F₁₄ layers (metal-containing layers) may be provided between SiO₂ layers (second low refractive index layer). Also, Na₃AlF₆ layers (metal-containing layers) may be provided between the SiO₂ layers (first low refractive index layers) as in FIG. 9B, or Na₃AlF₆ layers (metal-containing layers) may be provided between SiO₂ layers (second low refractive index layer).

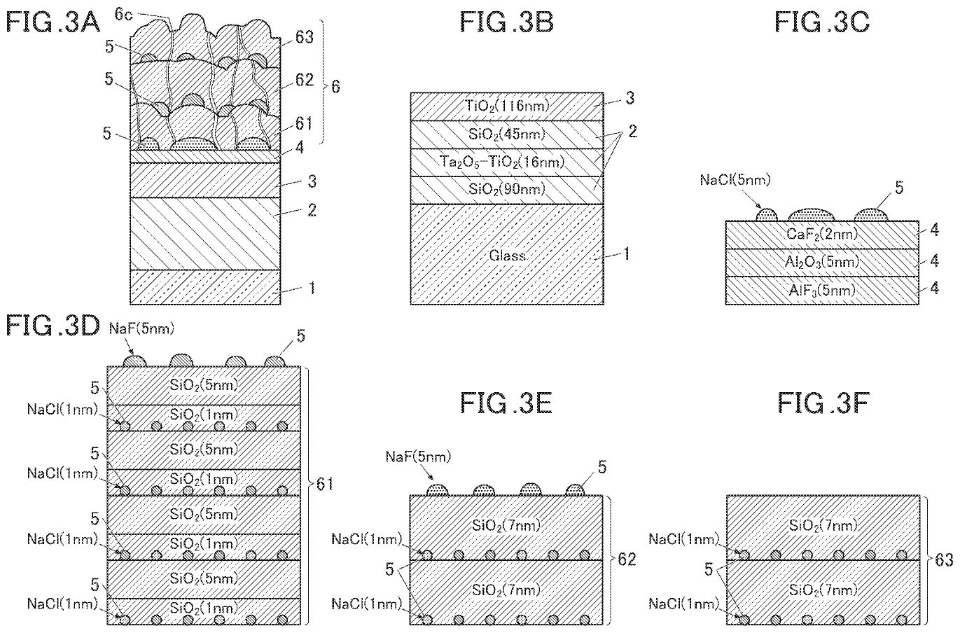

Furthermore, the metal-containing layer may form a part of the hydrophilic layer (coating layer) provided between a plurality of stacked SiO₂ layers, as described below. Specifically, NaCl layers (metal-containing layers) may be provided between SiO₂ layers (hydrophilic layers) as in FIG. 3D to FIG. 3F, and Na₅Al₃F₁₄ layers (metal-containing layers) may be provided between SiO₂ layers (hydrophilic layers) as in FIG. 4C.

The metal-containing layer may also serve as the fluorine-containing layer described above. In this case, the layer is preferably a metal-containing and fluorine-containing layer that contains fluorine and the alkali or alkaline earth metal. Such a metal-containing and fluorine-containing layer preferably contains a compound such as Na₅Al₃F₁₄ (thiolite), Na₃AlF₆ (cryolite), or BaF₂ (barium fluoride). Specific examples include the Na₅Al₃F₁₄ layers between the SiO₂ layers (first low refractive index layers) and between the SiO₂ layers (second low refractive index layers) shown in FIG. 4B and the Na₅Al₃F₁₄ layers between the SiO₂ layers (hydrophilic layers) shown in FIG. 4C. These Na₅Al₃F₁₄ layers are used as the metal-fluorine-containing layers. The same effect can also be obtained by stacking an Al₂O₃ layer and an NaF layer next to each other to form a mixed layer of Na, F, and Al.

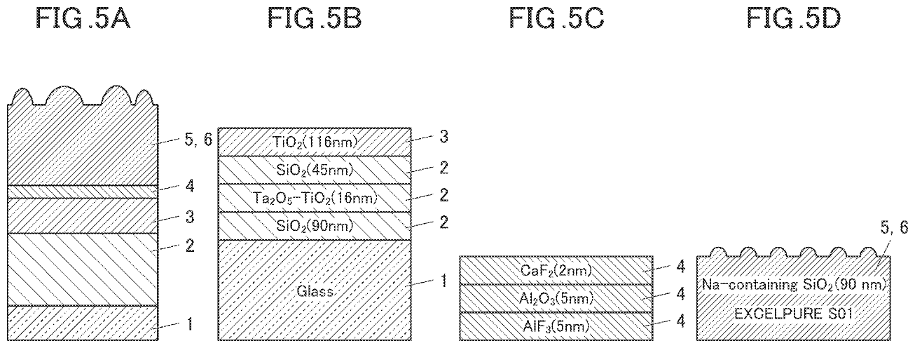

The metal-containing layer may also serve as the hydrophilic layer as well as the fluorine-containing layer. In this case, the layer is preferably a Na-containing SiO₂ layer (EXCELPURE S01 manufactured by CENTRAL AUTOMOTIVE PRODUCTS LTD.) (metal-containing and hydrophilic layer) shown in FIG. 5D containing a material as the hydrophilic layer and the alkali metal or the alkaline earth metal.

<Coating Film or Coating Layer>

The coating film or the coating layer of the present invention is a film or a layer that is a fine uneven structure provided on a surface of the base material or a constituent layer and covering at least the bumps and dents or an entire surface.

The coating film or coating layer may have an inorganic or organic material as components of the film with a property such as hydrophilic properties or antifog properties depending on the desired function.

For example, when a hydrophilic material is used, the finer the uneven structure, that is, the more the surface roughness becomes, the larger specific surface area (the area ratio of the rough surface to the plane before the uneven structure is provided), the smaller contact angle, and the more hydrophilic properties the hydrophilic surface has.

In the present invention, the term “film” refers to an object whose thickness is very small with respect to its surface area and is very thin. On the other hand, the term “layer” refers to stacked objects or each of the stacked objects.

The above mentioned film and layer are not limited to a continuous film and layer having an uncertain or a certain length or width, but may also be intermittent or dot-shaped isolated films or layers.

Therefore, the above mentioned “coating film” can also be formed as a “coating layer”.

Although the coating layer of the present invention is a layer that has a function of protecting the constituent materials of the underlying layer, it can also have various additional functions. Specifically, for example, the coating layer may function as a hydrophilic layer or an antifog layer.

(Hydrophilic Layer)

When the coating layer of the present invention is a hydrophilic layer, the hydrophilic layer preferably contains SiO₂ as the main component. In other words, the hydrophilic layer preferably includes the SiO₂ layer of the present invention as a part of its structure.

In the present invention, the phrase “the hydrophilic layer preferably contains SiO₂ as the main component” means that the ratio of SiO₂ among all the components constituting the hydrophilic layer is 80% by mass or more, preferably 90% by mass or more and 99.9% by mass or less, particularly preferably 97% by mass or more and 99.9% by mass or less.

The hydrophilic layer preferably includes a plurality of SiO₂ layers that are stacked. The hydrophilic layer preferably contains SiO₂ as the main component, and the metal-containing layer may be provided between the plurality of SiO₂ layers as described above.

Specifically, NaCl layers (metal-containing layers) may be provided between the SiO₂ layers (hydrophilic layers) of FIG. 3D to FIG. 3F, Na₃AlF₆ layers (metal-containing layers) may be provided between the SiO₂ layers (hydrophilic layers) of FIG. 9C, or the like.

With the metal-containing layers (for example, NaCl layers) provided between the hydrophilic layers, the fine uneven structure of the functional film becomes even finer.

In the present invention, a plurality of hydrophilic layers may be stacked. For example, the hydrophilic layer may include first to third hydrophilic layers 61 to 63 as shown in FIG. 3A. That is, the hydrophilic layer 6 shown in FIG. 3A has the first to third hydrophilic layers 61 to 63. The first hydrophilic layer 61 includes a plurality of NaCl layers and a plurality of SiO₂ layers alternately stacked. The second hydrophilic layer 62 and the third hydrophilic layer 63 each have the same layer configuration as the first hydrophilic layer 61. The first hydrophilic layer 61, the second hydrophilic layer 62, and the third hydrophilic layer 63 are stacked in this order.

The thicknesses of the SiO₂ layers constituting the first to third hydrophilic layers may be different from each other or may be the same. The number of NaCl layers and SiO₂ layers constituting the first to third hydrophilic layers can also be changed as needed.

Alternatively, the hydrophilic layer may consist of a single layer, for example, a SiO₂ layer containing Na (metal-containing and hydrophilic layer). Specifically, the hydrophilic layer may be formed by application of EXCELPURE S01 (manufactured by CENTRAL AUTOMOTIVE PRODUCTS LTD.) as the SiO₂ material containing Na.

The entire thickness of the hydrophilic layer is preferably in the range of 5 to 5000 nm, and particularly preferably in the range of 50 to 500 nm.

When the SiO₂ layers are stacked as described above, the thickness of each SiO₂ layer is preferably in the range of 5 to 50 nm, and SiO₂ layers of different thicknesses are preferably stacked alternately. In this case, units each consisting of a thin lower SiO₂ layer and a thick upper SiO₂ layer are preferably stacked (for example, see FIG. 3D to FIG. 3F)

The thickness of the NaCl layer, Na₅Al₃F₁₄ layer, or the Na₃AlF₆ layer between the SiO₂ layers is preferably in the range of 0.1 to 10 nm.

The hydrophilic layer is preferably formed by the thy process. Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred.

In particular, the formation of a thin SiO₂ layer by IAD followed by the formation of a thick SiO₂ layer by vacuum vapor deposition without IAD is preferable because the formed film can be porous and can strongly adheres to the underlying layer. The rotation speed of the base material is preferably slow. It is preferred to tilt the base material with respect to the angle of incidence of the atoms to form layers using the shading effect. This allows for the formation of a porous film.

The IAD method described above is a method to make a dense film by applying the high kinetic energy of ions, and the formed film has high adhesion strength. For example, in the ion beam method, ionized plasma particles emitted by the ion source hit the adhered material and form a film on the surface of the base material.

<Photocatalytic Layer>

The photocatalytic layer according to the present invention preferably contains TiO₂ as a metal oxide having a photocatalyst function as the main component, in that a high refractive index can be achieved, and optical reflectance of the functional film can be reduced.

In the present invention, the phrase “the photocatalytic layer preferably contains TiO₂ as the main component” means that the ratio of TiO₂ among all the components constituting the photocatalytic layer is 80% by mass or more, preferably 90% by mass or more and 99.9% by mass or less, particularly preferably 97% by mass or more and 99.9% by mass or less.

The “photocatalyst function” of the present invention refers to the organic matter decomposition effect by the photocatalyst. When TiO₂ having a photocatalytic property is irradiated with ultraviolet light, the active chemical species such as activated oxygen or hydroxyl radicals (·OH radicals) are generated after electrons are emitted, and decomposes organic matter by its strong oxidizing power. The photocatalytic layer containing TiO₂ can be added to the functional film of the present invention to prevent stains such as organic matter adhering to an optical member from contaminating the optical system.

The photocatalytic layer is preferably formed by the dry process. Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred. IAD is particularly preferred.

Between the adjacent bumps and dents, the fine uneven structure of the present invention preferably has a gap through which the active chemical species generated in the photocatalyst can pass. Specifically, as shown in FIG. 1, pores 6c are preferably formed in the coating layer 6. The pores 6c are formed due to the porous structure of the coating layer 6 formed by the dry process on the metal-containing layer 5. Due to the shading effect that occurs when a film is formed with vapor-deposited particles from a certain direction on the metal-containing layer 5, many pores remain in the vicinity of the unevenness. Therefore, rotation during film formation is preferably slow or intermittently stopped. It is also preferable to tilt the base material with respect to the angle of incidence of the vapor-deposited atoms to form films using the shading effect. This allows for the formation of a porous film.

Preferably, the pores 6c pass between the particles of the metal-containing layer 5 and through the fluorine-containing layer 4, and are connected to the photocatalytic layer 3.

The average diameter of the pores 6c is preferably in the range of 0.1 to 10 nm.

Whether or not such pores (gaps) are formed can be recognized by checking whether or not the surface of the functional film has a photocatalytic effect. It can be determined, for example, by irradiating a sample that is colored with a methylene blue ink pen with ultraviolet light at an integrated light intensity of 20 J at 20° C. and 80% RH and by evaluating the color change of the pen step by step. Specific examples of a photocatalyst performance test on self-cleaning using ultraviolet light irradiation include the methylene blue degradation method (ISO 10678 (2010)) and the Resazurin ink test (ISO 21066 (2018)).

Even when the functional film does not have a photocatalytic layer (for example, antifog functional film), whether or not the pores are formed is determined by providing a photocatalytic layer on the base material, forming an antifog layer and the like on the photocatalytic layer, coloring the film with a methylene blue ink pen, irradiating it with ultraviolet light, and then evaluating the color change of the pen step by step.

<Reflectance Adjustment Layer>

The reflectance adjustment layer of the present invention preferably includes at least one low refractive index layer and at least one high refractive index layer.

The reflectance adjustment layer consists of, for example, a first low refractive index layer on the base material, a high refractive index layer, and a second low refractive index layer, in this order. The following is an example of the material and thickness of each layer, which does not limit the present invention.
1) First low refractive index layer: constituent material=SiO₂, layer thickness=90 mn
2) High refractive index layer: constituent material=Ta₂O₅—TiO₂ (Product Name: OA-600, manufactured by Canon Optron, Inc.), layer thickness=16 nm
3) Second low refractive index layer: constituent material=SiO₂, layer thickness=45 mn

The above configuration is merely an example, and the order of the low refractive index layer and the high refractive index layer may be changed, and even a larger number of low refractive index layers and high refractive index layers may be stacked.

<First Low Refractive Index Layer and Second Low Refractive Index Layer>

The first low refractive index layer and the second low refractive index layer of the present invention are configured from materials having a refractive index of less than 1.7, and preferably contain SiO₂ as the main component in the present invention. However, the first low refractive index layer and the second low refractive index layer according to the present invention also preferably contain a further metal oxide. A mixture of SiO₂ partly including Al₂O₃ or MgF₂ is also preferred from the viewpoint of optical reflectance.

<High Refractive Index Layer>

In the present invention, the high refractive index layer is configured from a material having a refractive index of 1.7 or more. The material of the high refractive index layer is, for example, a mixture of an oxide of Ta and an oxide of Ti, a mixture of an oxide of Ti, an oxide of Ta, an oxide of La, and an oxide of Ti, and the like. The metal oxide used in the high refractive index layer preferably has a refractive index of 1.9 or more. In the present invention, the metal oxide preferably used in the high refractive index layer is Ta₂O₅ or TiO₂, and more preferably Ta₂O₅.

In the present invention, the thickness of the reflectance adjustment layer including the high refractive index layer(s) and the low refractive index layer(s) is not particularly limited. However, from the viewpoint of anti-reflective performance, it is preferably 500 nm or less, and more preferably in the range of 50 to 500 nm. When the thickness is 50 nm or more, the optical properties of anti-reflection can be achieved. When the thickness is 500 nm or less, the error sensitivity is reduced, and the ratio of products with excellent spectral characteristics of the lens can be increased.

The thickness of the first low refractive index layer in the above configuration example is preferably in the range of 5 to 150 nm, the thickness of the second low refractive index layer is preferably in the range of 5 to 100 nm, and the thickness of the high refractive index layer is preferably in the range of 1 to 70 nm.

The method of forming the reflectance adjustment layer including the low refractive index layer(s) and the high refractive index layer(s) is not particularly limited, but preferably the dry process is used.

Examples of the dry process applicable to the present invention based on vapor deposition include vacuum vapor deposition, ion beam vapor deposition, ion plating, ion-assisted vapor deposition (IAD), and the like. Examples of the dry process applicable to the present invention based on sputtering include sputtering, ion beam sputtering, magnetron sputtering, and the like. Among these, vacuum deposition, IAD, or sputtering is preferred. IAD is particularly preferred.

<Base Material>

The base material from which the functional film is formed is not restricted, and preferably consists of an inorganic material, an organic material, or a combination thereof.

Examples of the inorganic material include H-ZLAF55D glass, H-ZLAF55F glass, TaFD glass, fused quartz glass, synthetic quartz glass, glass lens, silicon, chalcogenide, or chromium.

Examples of the organic material include polyethylene terephthalate (PET), acrylic resins, vinyl chloride resins, cyclo-olefin polymers (COP), polymethyl methacrylate resins (PMMA), polycarbonate resins (PC), polypropylene (PP), and polyethylene (PE). Examples of UV curable resins are radical polymerization type acrylate resin, urethane acrylate, polyester acrylate, polybutadiene acrylate, epoxy acrylate, silicone acrylate, amino resin acrylate, and en-thiol resins, and cationic polymerization type vinylether resins, alicyclic epoxy resins, glycidyl ether epoxy resins, urethane vinylethers, and polyester vinylethers. Examples of thermosetting resins include epoxy resins, phenolic resins, unsaturated polyester resins, urea resins, melamine resins, silicone resins, polyurethane, and the like. The base material may be an inorganic material such as glass with a film made of an organic material on the inorganic material.

In the present invention, when the functional film of the present invention is used for optical devices as described below, glass is preferably used as the base material from the viewpoint of transparency. When the functional film of the present invention is used for an inkjet head, silicon is preferably used as the base material. When the functional film is used for a mold, SiC, ultra-hard alloys, or the like is preferably used as the base material.

The base material of the present invention contains an alkali metal or an alkaline earth metal and when the content of the alkali metal or the alkaline earth metal in the base material is 3% by mass or less, the improvement effect of high temperature and high humidity due to fluoride becomes more significant. In particular, when the content is 1% by mass or less, the above-mentioned improvement effect is even more significant.

<Intermediate Layer>

In addition to the layers each mentioned above, the functional film of the present invention may have an intermediate layer (not shown) that is provided on the base material and adjusts the shape of the particles contained in the particle containing layer. When the reflectance adjustment layer or the photocatalytic layer is provided on the base material, the intermediate layer is preferably provided on the reflectance adjustment layer and the photocatalytic layer.

The intermediate layer preferably contains an inorganic material as a main component. Examples of the inorganic material are not limited to, but include Ta₂O₅—TiO₂ (OA600 manufactured by Canon Optron, Inc.), HfO₂, Y₂O₃, LaF, CeF, SiO₂, and the like. SiO₂ is particularly preferred in terms of hydrophilic properties.

The intermediate layer is preferably formed by the dry process. Examples of the dry process based on vapor deposition include vacuum vapor deposition, ion beam vapor deposition, ion plating, ion-assisted vapor deposition (IAD), and the like. Examples of the dry process based on sputtering include sputtering, ion beam sputtering, magnetron sputtering, and the like. Among these, vacuum vapor deposition, IAD, or sputtering is preferred. IAD is particularly preferred.

The intermediate layer formed by the dry process is preferably subjected to etching to form dents so that the underlying photocatalytic layer effectively exhibits the photocatalytic effect. In other words, as described later, the pores 6c of the coating layer 6 are preferably arranged in the dents. This allows the pores 6c to be connected to the photocatalytic layer 3, and the active chemical species generated in the photocatalytic layer 3 to pass through the pores 6c.

The average diameter of the dents is preferably in the range of 10 to 1000 nm. The average diameter of the dents can be obtained using the electron microscope (S-4800 manufactured by Hitachi High-Tech Science Corporation).

The thickness of the intermediate layer is preferably in the range of 0.1 to 100 nm.

[Fine Uneven Structure of Functional Film]

As described above, the functional film of the present invention preferably has a fine uneven structure on its surface, and the mutual positional relationship and shape of the plurality of bumps and dents of the fine uneven structure are preferably random and have no regularity in terms of identity or periodicity to the extent so as not to generate diffracted light. This provides the effect of improved visibility and good functionality as an optical component. Furthermore, the functions of the functional film of the present invention, such as the hydrophilic properties or the antifog properties, can be enhanced.

In the present invention, the term “bumps and dents” encompasses an uneven layer and a plurality of particles that do not appear to be a layer.

In the present invention, “an extent such that no diffracted light occurs” means that there occurs no diffracted light due to interference of reflected light beams from the bumps and dents or due to interference of an incident light beam and a reflected light beam.

When a fine uneven structure is formed by an etching process using lithography or by nanoimprinting using a mold, diffracted light occurs because the uneven structure has regularity. However, in the present invention, since the fine uneven structure is formed by the dry process as described later, an irregular (random) fine structure is formed, and thus no diffracted light occurs.

The presence or absence of the diffracted light can be checked, for example, by placing a sample of the functional film between the helium-neon laser source and a screen, irradiating the screen with the laser through the sample, and then visually checking the laser on the screen.

In the present invention, the “fine uneven structure” means a structure having a shape of multiple bumps and dents that are fine enough to express the action as a functional film, and satisfies at least the following: the average height of the bumps is 1 μm or less with respect to the bottom of the dent, in other words, the average depth of the dents is 1 μm or less.

The fine uneven structure preferably has an arithmetic average roughness Ra of bumps in the range of 2 to 50 nm, a maximum height of bumps in the range of 10 to 500 nm, and an average diameter of the bumps in the range of 10 to 1000 nm in the vertical cross section, such that the abrasion resistance and functional film properties can be amplified.

<Arithmetic Average Roughness Ra>

In the present invention, the arithmetic average roughness Ra of the bumps is preferably within the range of 10 to 40 nm, particularly preferably within the range of 15 to 30 nm.

The arithmetic average roughness Ra of the bumps is the average of roughness measured at 10 or more bumps using an atomic force microscope (L-Trace, manufactured by Hitachi High-Tech Science Corporation) and satisfies the aforementioned conditions.

<Maximum Height>

In the present invention, the maximum height of the bumps is preferably within the range of 50 to 200 nm, particularly preferably within the range of 70 to 150 nm.

In the present invention, “the maximum height of the bumps” is the distance h from the lowest bottom surface to the outermost (uppermost) surface of the bump 6d in the vertical section (cross-section along the thickness direction) of the fine uneven structure, for example, as shown in FIG. 1.

The maximum height of the bumps is the maximum value of heights of 10 or more bumps measured using an atomic force microscope (L-Trace, manufactured by Hitachi High-Tech Science Corporation) and satisfies the aforementioned conditions.

<Average Diameter>

In the present invention, the average diameter of the bumps is preferably within the range of 30 to 500 nm, particularly preferably within the range of 50 to 200 nm.

In the present invention, “the average diameter of the bumps” is obtained when the fine uneven structure is viewed from the top, that is, when the entire fine uneven structure is photographed with an electron microscope from the top and observed. For example, it is the average diameter L of the bump 6d as shown in FIG. 1.

The average diameter of the bumps can be obtained using an electron microscope (S-4800 manufactured by Hitachi High-Tech Science Corporation). Specifically, the average of 10 or more measurements of the bumps satisfies the aforementioned conditions.

As described below, the arithmetic average roughness Ra, maximum height, and average diameter of the bumps can be controlled to be within the aforementioned ranges using the production method of the functional film of the present invention. Specifically, at least one metal-containing layer and the coating layer on the metal-containing layer are preferably formed by the dry process.

The functional film of the present invention preferably has a total transmittance of 70% or more in terms of excellent optical properties, and particularly preferably in the range of 80 to 99%. The greater the total transmittance, the higher the transparency, which is preferred.

The total transmittance of the functional film was measured using a haze meter NDH5000SP (manufactured by Nippon Denshoku Industries Co., Ltd.).

The total transmittance can be adjusted to 70% or more by appropriate selection of materials for each layer of the functional film.

In the following, specific examples of XPS analysis conditions applicable to the composition analysis of the functional films of the present invention are shown.

Analysis device: Quantera SXM manufactured by ULVAC-PHI, Inc.

X-ray source: monochromatized Al-Kα, 15 kV-25 W

Sputter ion: Ar (2 kV)

Depth profile: Measurements are repeated at predetermined thickness intervals, and a depth profile in the depth direction is obtained. Specifically, measurements are performed every 2.5 nm in the sputter thickness as SiO₂ to obtain data every 2.5 nm in the depth direction.

Quantification: Background is determined by Shirley method and quantification is made from the obtained peak area using the relative sensitivity coefficient method. Data are processed using analysis software MultiPak (manufactured by ULVAC-PHI, Inc.).

X-ray photoelectron spectroscopy (XPS) is a method of analyzing the constituent elements of a sample by irradiating the sample with X-rays and measuring the energy of the generated photoelectrons.

The elemental concentration distribution curve in the thickness direction of the functional film of the present invention (hereinafter referred to as “depth profile”) is obtained by sequential analysis of surface composition while exposing the inside of the functional film from the surface by combining measurement of the surface elemental composition of the sample and sputtering with a rare gas ion such as argon (Ar).

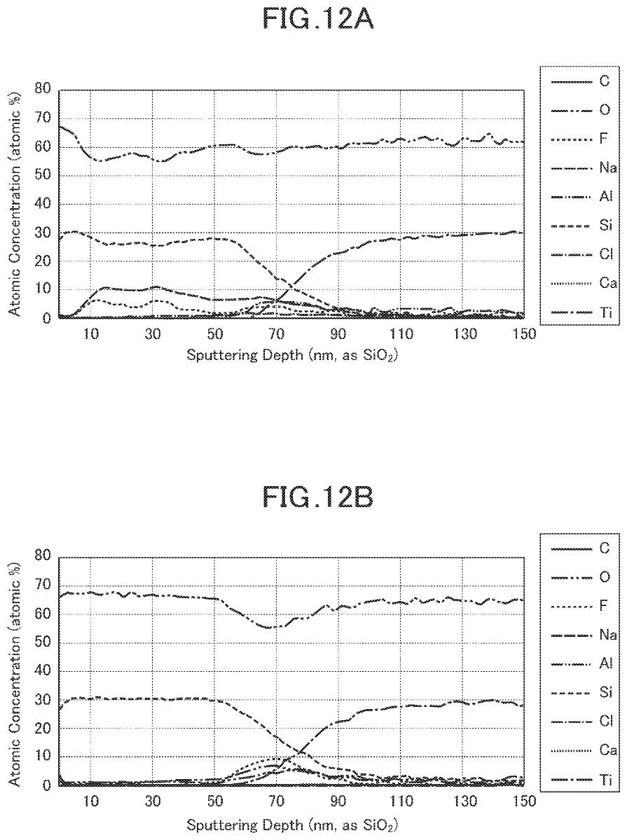

The distribution curve obtained by such XPS depth profile measurement can be prepared, for example, by setting the atomic concentration ratio of each element (unit: atomic %) on the vertical axis and the etching time (sputtering time) on the horizontal axis (see FIG. 12A and FIG. 12B, for example).

In the element distribution curve with etching time on the horizontal axis, etching time is approximately correlated with the distance from the surface of the functional film to the measurement position in the layer thickness direction of the functional film. Therefore, “the distance from the surface of the functional film in the thickness direction of the functional film” can be the distance from the surface of the functional film calculated from the relationship between etching rate and etching time, which was applied in the XPS depth profile measurement.

The rare gas ion sputtering method using argon (Ar) as the etching ion species can be used in such an XPS depth profile measurement. The etching rate can be measured for SiO₂ thermally oxidized film whose thickness is known in advance, and the etching depth is often expressed as an equivalent of a SiO₂ thermally oxidized film.

By the composition analysis as described above, it is possible to observe, for example, the change in composition of the functional film immediately after film formation and after a long time (234 hours) of placement in a high temperature and high humidity environment (85° C. and 85% RH) (see, for example, FIG. 12A and FIG. 12B).

[Contact Angle of Functional Film]

The contact angle A1 of the surface of the functional film of the present invention after 100 hours of storage in a 85° C. and 85% RH environment (high temperature and high humidity environment) is preferably 30° or less in terms of visibility, and more preferably 10° or less.

The contact angle contact angle A1 was measured as follows.

The functional film was left in an environment of 85° C. and 85% RH for 100 hours. Then, 1.0 μL of pure water was dropped onto the surface of the functional film in an environment of 23° C. and 50% RH. The static contact angle measured 5 seconds after the drop using the contact angle measurement device G-1 (manufactured by ERMA Inc.) was defined as the contact angle A1.

The contact angle A2 of the surface of the functional film of the present invention after 100 hours of storage in a 85° C. (high temperature) and dry environment is preferably 10° or less.

The contact angle A2 can be measured in the same manner as the contact angle A1, except that the environment is changed to 85° C. and dry environment. The 85° C. and dry environment can be achieved by setting the temperature to 85° C. using a compact high-temperature chamber ST-120 (manufactured by ESPEC CORP.).

In terms of visibility, the contact angle of the surface of the functional film of the present invention is preferably 30° or less after the rub resistance test in which the surface of the functional film is rubbed with the scourer (Kamenoko Tawashi) 100 times back and forth with a load of 0.1 kg.

The Kamenoko Tawashi (Product name: Palm Chibikko P) was manufactured by KAMENOKO-TAWASHI Nishio-Shoten Co., Ltd. After the rub resistance test in which the surface was rubbed 100 times back and forth with a load of 0.1 kg, the contact angle was measured using the contact angle measurement device G-1 (manufactured by ERMA Inc.) in the same manner as above.

Furthermore, in terms of visibility, there are preferably no visible scratches generated on the surface of the functional film after the rub resistance test in which the surface of the functional film was rubbed with the Kamenoko Tawashi 100 times back and forth with a load of 0.1 kg.

Here, “no visible scratches generated on the surface of the functional film” is defined as follows. The functional film is observed using an optical microscope SZX10 (manufactured by Olympus Corporation) at a magnification of 10 times or more, and ten areas suspected to include a scratch(es) and ten areas without a scratch are determined. The reflectances of the ten areas suspected to include a scratch and the reflectances of the ten areas without a scratch are each measured in the wavelength range of 420 to 670 nm using a micro-area spectral reflectance measurement device USPM-RU (manufactured by Olympus Corporation). The average reflectance of the ten areas suspected to include a scratch is compared with the average reflectance of the ten areas without a scratch. When the average reflectances differ by 1% or more, the functional film is defined to have a scratch. When the average reflectances differ by less than 1%, it is defined that there is “no visible scratches on the surface of the functional film.”

[Production Method of Functional Film]

The production method of the functional film of the present invention is characterized by the process of forming a fluorine-containing layer containing fluorine on the base material.

Furthermore, the production method of the functional film of the present invention preferably includes a process of forming a metal-containing layer containing an alkali metal or an alkaline earth metal by the dry process. Furthermore, the process of forming the metal-containing layer preferably includes an exposure process (aging process) to an environment containing moisture to form the metal-containing layer in that the metal-containing layer can be easily formed in the form of uniformly distributed particles and that the properties of the resulting functional film are excellent.

During such a process of forming the metal-containing layer, the uneven structure is formed.

Specifically, the material of the metal-containing layer is formed in a layer by the dry process on the base material. As a result, a layer that serves as a precursor of the metal-containing layer is formed. This layer that functions as a precursor is not yet in a granular state. The precursor is then exposed to an environment containing moisture in the aging process to become a granular metal-containing layer.

Exposure to an environment containing moisture means, for example, placing the precursor in a dry layer forming device to the outside.

The time of exposure in the environment (aging period) is preferably in the range of 1 minute to 300 hours.

After the aging process, the SiO₂ layer is preferably formed on the metal-containing layer by the dry process in that fine uneven structures and porous structures can be easily produced, and the metal-containing layer can be fixed with the SiO₂ layer so as not to be peeled off.

In the process of forming the fluorine-containing layer, the fluorine-containing layer is preferably a plurality of granular layers of less than 10 nm and alternately stacked with different layers, such that the fine uneven structure is formed on the surface in that the high temperature and high humidity resistance and the high temperature resistance can be improved. Examples of the different layers, other than the fluorine-containing layer, includes the SiO₂ layers shown in FIG. 4B, FIG. 4B, and the like.

The fluorine-containing layer formation is preferably conducted at a temperature of 200° C. or higher, because the higher the temperature, the more obvious the unevenness becomes.

In the production method of the functional film of the present invention, it is preferred to form all layers by the dry process in the process of forming the functional film because it improves the adhesion and the rub resistance and allows for easy production of the fine uneven structure and porous structure. However, at least one layer may be formed by the wet process in the process of forming the functional film. Specifically, at least the metal-containing layer is preferably formed by the dry process, while the SiO₂ layer may be formed by a wet process (i.e., by application).

FIG. 2A to FIG. 2C are process diagrams showing an example of the production method of the functional film. FIG. 2A to FIG. 2C show examples of the production method of the present invention and do not limit the production method of the present invention.

As shown in FIG. 2A, the reflectance adjustment layer 2 and the photocatalytic layer 3 are formed on the base material 1 by the method described above. On the photocatalytic layer 3, the fluorine-containing layer 4 is formed.

Preferably, the fluorine-containing layer is formed by the dry process. The dry process is preferably the resistance heating vacuum vapor deposition.

The layer forming material of the fluorine-containing layer may be any material that contains at least fluorine, and may contain aluminum, calcium, sodium, and other elements in addition to fluorine. Furthermore, a part of the layer forming material preferably contains at least one of or constituent elements of at least one of AlF₃, Al₂O₃, CaF₂, NaF, Na₅Al₃F₁₄ (thiolite), and Na₃AlF₆ (cryolite).

Next, as shown in FIG. 2B, the metal-containing layer 5 is formed on the fluorine-containing layer 4 by the dry process. The precursor of the metal-containing layer is formed by the dry process.

The dry process is preferably the resistance heating vacuum vapor deposition.

The layer forming material of the metal-containing layer may be any material containing the alkali metal or the alkaline earth metal as described above, for example, Li (lithium), Na (sodium), K (potassium), Rb (rubidium), Cs (cesium), Fr (francium), Be (beryllium), Mg (magnesium), Ca (calcium), Sr (strontium), Ba (barium), and Ra (radium). In particular, Na (sodium) or Mg (magnesium) are preferred. Specific examples include NaCl, NaF, MgCl₂·6H₂O, Na₅Al₃F₁₄, and Na₃AlF₆.

Next, after layer forming with the layer forming material as shown in FIG. 2B, the process of exposure to an environment that contains moisture (aging process) is preferably performed. This causes the above layer forming material to take in water from the environment and become a particulate form. Then, the metal-containing layer 5 can be easily formed in the form of uniformly distributed particles and the properties of the resulting functional film can be excellent. In other words, the surface of the metal-containing layer 5 becomes particulate and a finer uneven structure is formed when the inorganic salt contains water.

The period of the aging process is preferably in the range of 1 minute to 300 hours.

Next, as shown in FIG. 2C, a SiO₂ layer (coating layer 6) is formed on the metal-containing layer 5 after the aging process by the dry process.

The dry process is preferably the IAD method as described above. A layer made of the coating layer material according to the type of the functional film is formed.

Examples of the coating layer material include SiO₂, Al₂O₃, and the like.

The coating layer 6 is formed on the metal-containing layer 5 in this way so that the porous functional film 100 of the present invention having the pores 6c and a surface with the fine uneven structure can be obtained.

[Applications of Functional Film]

The functional film of the present invention has various functions depending on the layer configuration of the functional film. For example, when a hydrophilic layer is applied as the coating layer, it can function as a hydrophilic functional film. When an antifog layer is applied as the coating layer, it can function as an antifog functional film.

<Optical Device>

The functional film of the present invention can be applied to an optical device.

Preferred examples of optical device include lenses, cover glass for lenses, antimicrobial cover members, antifungal coating members, or mirrors. The functional film of the present invention is suitable for automotive lenses, communication lenses, antibacterial lenses for endoscopes, members of PCs and smartphones, antibacterial cover members, glasses, ceramics for toilets and dishes, anti-mold coating for baths and sinks, or building materials (windows). Among them, it is especially suitable for automotive lenses.

The base material of the optical device to which the functional film of the present invention is applied is preferably glass from the viewpoint of transparency, and the coating layer of such a functional film is preferably the hydrophilic layer or the antifog layer described above. In other words, the main component of the coating layer is preferably SiO₂, which is a Si-containing material, from the viewpoint of easily obtained hydrophilic properties.

### EXAMPLES

In the following examples, the present invention will be described in detail, but is not limited to these examples. In the following examples, unless otherwise noted, the operations were performed at room temperature (25° C.). Unless otherwise noted, “%” and “part” mean “% by mass” and “part by mass,” respectively.

Functional films 1 to 21 of Examples (Inv.) 1 to 18 of the present invention and Comparative Examples (Comp.) 1 to 3 were produced as shown below.

In the formation of each of the following layers, when the same device is used as in the previous and following processes, the layers are assumed to be formed continuously without being exposed to the atmosphere, unless otherwise noted. When a device different from those in the preceding and following processes is used, it is assumed to be exposed to the atmosphere.

### Example 1

### [Production of Functional Film]

A functional film with the layer configuration shown in FIG. 3A to FIG. 3F was produced. FIG. 3A is a schematic diagram of the entire layer configuration of the functional film of Example 1. FIG. 3B is a schematic diagram of the layer configuration of the base material 1, the reflectance adjustment layer 2, and the photocatalytic layer 3 in FIG. 3A. FIG. 3C is a schematic diagram of the layer configuration of the fluorine-containing layer 4 and the metal-containing layer 5 having unevenness in FIG. 3A. FIG. 3D to FIG. 3F are schematic diagrams of the layer configurations of the first to third hydrophilic layers 61 to 63, respectively, with the metal-containing layers 5 having unevenness in FIG. 3A.

<Preparation of Base Material>

As the base material, a lens made of a glass material H-ZLAF55D (manufactured by CDGM GLASS CO., LTD.) processed for an automotive lens was prepared. This lens was cleaned for 600 seconds using a UV Ozone Cleaner (manufactured by Technovision, Inc.).

<Formation of Reflectance Adjustment Layer>

### (Formation of First Low Refractive Index Layer)

On the base material, a first low refractive index layer containing SiO₂ (SiO₂ layer, 90 nm) was formed using an IAD Vacuum Coating Machine (BIS-1300DNN, manufactured by Shincron Co., Ltd.) under the following conditions.

<<Conditions in Chamber>>

Heating temperature: 370° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the first low refractive index layer: SiO₂ (Product Name: SiO₂, manufactured by Canon Optron, Inc.)

The base material was installed in the IAD Vacuum Coating Machine, SiO₂ was loaded as the layer forming material in a first evaporation source, and the first low refractive index layer (SiO₂ layer) having a thickness of 90 nm was formed by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar. (sccm: standard cubic centimeter per minute, 1 sccm=1.69×10⁻³ Pa·m³/sec)

(Formation of High Refractive Index Layer)

On the first low refractive index layer, a high refractive index layer (Ta₂O₅—TiO₂, 16 nm) was continuously formed using the IAD Vacuum Coating Machine (BIS-1300DNN, manufactured by Shincron Co., Ltd.) under the following conditions.

<<Conditions in Chamber>>

Heating temperature: 370° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the high refractive index layer: Ta₂O₅—TiO₂, (Product Name: OA-600, manufactured by Canon Optron, Inc.)

The above layer forming material was loaded in a second evaporation source of the IAD Vacuum Coating Machine, and the high refractive index layer having a thickness of 16 nm (Ta₂O₅—TiO₂, 16 nm) was formed on the first low refractive index layer by vapor deposition at a deposition rate of 4 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar. At this time, gas control was performed to keep the chamber pressure at 2×10⁻² Pa by introducing O₂ gas from an automatic pressure controller (hereinafter abbreviated as “APC”).

(Formation of Second Low Refractive Index Layer)

On the high refractive index layer, a second low refractive index layer (SiO₂ layer, 45 nm) was continuously formed using the IAD Vacuum Coating Machine (BIS-1300DNN, manufactured by Shincron Co., Ltd.) under the following conditions.

<<Conditions in Chamber>>

Heating temperature: 370° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the second low refractive index layer: SiO₂ (Product Name: SiO₂, manufactured by Canon Optron, Inc.)

SiO₂ was loaded as the layer forming material in the first evaporation source of the IAD Vacuum Coating Machine, and the second low refractive index layer (SiO₂ layer) having a thickness of 45 nm was formed on the high refractive index layer by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

<Formation of Photocatalytic Layer>

On the second low refractive index layer, a photocatalytic layer (TiO₂ layer, 116 nm) was formed continuously using the IAD Vacuum Coating Machine (BIS-1300DNN, manufactured by Shincron Co., Ltd.) under the following conditions.

<<Conditions in Chamber>>

Heating temperature: 370° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the photocatalytic layer: TiO₂ (Product Name: TOP (Ti₃O₅), manufactured by Fuji Titanium Industry Co., Ltd.)

The above layer forming material was loaded in a third evaporation source of the IAD Vacuum Coating Machine, and the photocatalytic layer (TiO₂ layer) having a thickness of 116 nm was formed on the second low refractive index layer by vapor deposition at a deposition rate of 2 Å/sec.

IAD was performed at an acceleration voltage of 300 V, acceleration current of 300 mA, suppressor voltage of 1000 V, and neutralization current of 600 mA, and the IAD introduction gas was 50 sccm of O₂, 10 sccm of Ar gas, and 10 sccm of neutral gas Ar. At this time, gas control was performed to keep the chamber pressure at 3×10⁻² Pa by introducing O₂ gas from the APC.

<Formation of Fluorine-Containing Layer>

After the photocatalytic layer was formed, on the photocatalytic layer, the fluorine-containing layer (AlF₃ layer 5 nm/Al₂O₃ layer 5 nm/CaF₂ layer 2 nm) was formed continuously using the IAD Vacuum Coating Machine (BIS-1300DNN, manufactured by Shincron Co., Ltd.) under the following conditions.

<<Conditions in Chamber>>

Heating temperature: 370° C.

Starting vacuum: 5.0×10⁻³ Pa

<<Evaporation Source of Layer Forming Material>>

Electron gun

<<IAD Ion Source>>

None

<Formation of Metal-Containing Layer Having Unevenness>

The metal-containing layer having unevenness (NaCl layer, 5 nm) was formed on the CaF₂ layer (2 nm) of the fluorine-containing layer by the following procedure.

(NaCl Layer)

The substrate was taken out of the IAD Vacuum Coating Machine and placed in the following layer forming device, and the metal-containing layer made of NaCl (NaCl layer, 5 nm) was formed on the formed CaF₂ layer.

A deposition device (BMC-800T, manufactured by Shincron Co., Ltd.) was used for resistance heating vapor deposition of NaCl under the following conditions.

<<Conditions in Chamber>>

Heating temperature: 25° C.

Starting vacuum: 5.0×10⁻³ Pa

Deposition rate: 1 Å/sec.

Next, the substrate was once opened to the atmosphere to particulate the NaCl, and a metal-containing layer having unevenness (NaCl layer, 5 nm) was obtained.

<Formation of First Hydrophilic Layer>

On the metal-containing layer having unevenness (NaCl layer, 5 nm), a first hydrophilic layer composed of a SiO₂ layer (1 nm or 5 nm) including the NaCl layer (1 nm) of the metal-containing layer.

(NaCl Layer)

On the metal-containing layer having unevenness (NaCl layer, 5 nm), the NaCl layer (1 nm in thickness) of the metal-containing layer was further formed using the IAD Vacuum Coating Machine (BIS-1300DNN, manufactured by Shincron Co., Ltd.) under the following conditions.

<<Conditions in Chamber>>

Heating temperature: 30° C.

Starting vacuum: 5.0×10⁻³ Pa

<<Evaporation Source of Layer Forming Material>>

Electron gun

<<IAD Ion Source>>

None

(SiO₂ Layer)

After forming the metal-containing layer (NaCl layer, 1 nm), the substrate was placed in the following IAD Vacuum Coating Machine, and two SiO₂ layers (SiO₂ layer, 1 nm and SiO₂ layer, 5 nm) were formed on the metal-containing layer (NaCl layer, 1 nm).

On the metal-containing layer (NaCl layer, 1 nm), the SiO₂ layer (1 nm in thickness) was formed using the IAD Vacuum Coating Machine (BIS-1300DNN, manufactured by Shincron Co., Ltd.) under the following conditions.

<<Conditions in Chamber>>

Heating temperature: 30° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the hydrophilic layer: SiO₂ (Product Name: SiO₂, manufactured by Canon Optron, Inc.)

SiO₂ was loaded as the layer forming material in the first evaporation source of the IAD Vacuum Coating Machine, and the SiO₂ layer having a thickness of 1 nm was formed on the metal-containing layer (NaCl layer, 1 nm) by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

Next, the SiO₂ layer (5 nm in thickness) was formed under the same conditions except that the IAD was turned off. Thus, a unit consisting of the NaCl layer (1 nm)/SiO₂ layer (1 nm)/SiO₂ layer (5 nm) was formed. This unit was repeatedly formed three more times, and the first hydrophilic layer consisting of the four units was formed.

<Formation of Metal-Containing Layer Having Unevenness>

On the first hydrophilic layer that is the SiO₂ layer (5 nm), the metal-containing layer having unevenness (NaF layer, 5 nm) was formed by the following procedure.

(NaF Layer)

The substrate was taken out of the IAD Vacuum Coating Machine and placed in the following deposition device, and the metal-containing layer made of NaF (NaF layer, 5 nm) was formed on the formed SiO₂ layer (5 nm).

A deposition device (BMC-800T, manufactured by Shincron Co., Ltd.) was used for resistance heating vapor deposition of NaF under the following conditions.

<<Conditions in Chamber>>

Heating temperature: 25° C.

Starting vacuum: 5.0×10⁻³ Pa

Deposition rate: 1 Å/sec.

Next, the substrate was once opened to the atmosphere to particulate the NaF, and a metal-containing layer having unevenness (NaF layer, 5 nm) was obtained.

<Formation of Second Hydrophilic Layer>

On the metal-containing layer having unevenness (NaF layer, 5 nm), a second hydrophilic layer that is a SiO₂ layer (7 nm) including the NaCl layer (1 nm) of the metal-containing layer was formed.

(NaCl Layer)

On the metal-containing layer having unevenness (NaF layer, 5 nm), the metal-containing layer that is a NaCl layer (1 nm in thickness) was further formed using the IAD Vacuum Coating Machine (BIS-1300DNN, manufactured by Shincron Co., Ltd.) under the following conditions.

<<Conditions in Chamber>>

Heating temperature: 30° C.

Starting vacuum: 5.0×10⁻³ Pa

<<Evaporation Source of Layer Forming Material>>

Electron gun

<<IAD Ion Source>>

None

(SiO₂ layer)

After forming the metal-containing layer (NaCl layer, 1 nm), the substrate was placed in the following IAD Vacuum Coating Machine, and one SiO₂ layer (SiO₂ layer 7 nm) was formed on the formed metal-containing layer (NaCl layer, 1 nm).

On the metal-containing layer (NaCl layer, 1 nm), the SiO₂ layer (7 nm in thickness) was formed using the IAD Vacuum Coating Machine (BIS-1300DNN, manufactured by Shincron Co., Ltd.) under the following conditions.

<<Conditions in Chamber>>

Heating temperature: 30° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the hydrophilic layer: SiO₂ (Product Name: SiO₂, manufactured by Canon Optron, Inc.)

SiO₂ was loaded as the layer forming material in the first evaporation source of the IAD Vacuum Coating Machine, and the SiO₂ layer having a thickness of 7 nm was formed on the metal-containing layer by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

Thus, a unit consisting of the NaCl layer (1 nm)/SiO₂ layer (7 nm) was formed. This unit was repeatedly formed once more, and the second hydrophilic layer consisting of the two units was formed.

<Formation of Metal-Containing Layer Having Unevenness>

The metal-containing layer having unevenness (NaF layer, 5 nm) was formed on the second hydrophilic layer that is the SiO₂ layer (7 nm) by the following procedure.

(NaF Layer)

The substrate was taken out of the IAD Vacuum Coating Machine and placed in the following deposition device, and the metal-containing layer of NaF (NaF layer, 5 nm) was formed on the formed SiO₂ layer (7 nm).

A deposition device (BMC-800T, manufactured by Shincron Co., Ltd.) was used for resistance heating vapor deposition of NaF under the following conditions.

<<Conditions in Chamber>>

Heating temperature: 25° C.

Starting vacuum: 5.0×10⁻³ Pa

Deposition rate: 1 Å/sec.

Next, the substrate was once opened to the atmosphere to particulate the NaF, and a metal-containing layer having unevenness (NaF layer, 5 nm) was obtained.

<Formation of Third Hydrophilic Layer>

On the metal-containing layer having unevenness (NaF layer, 5 nm), a third hydrophilic layer that is a SiO₂ layer (7 nm) including the NaCl layer (1 nm) of the metal-containing layer was formed.

(NaCl Layer)

On the metal-containing layer having unevenness (NaF layer, 5 nm), the metal-containing layer that is a NaCl layer (1 nm in thickness) was further formed using the IAD Vacuum Coating Machine (BIS-1300DNN, manufactured by Shincron Co., Ltd.) under the following conditions.

<<Conditions in Chamber>>

Heating temperature: 30° C.

Starting vacuum: 5.0×10⁻³ Pa

<<Evaporation Source of Layer Forming Material>>

Electron gun

<<IAD Ion Source>>

None

(SiO₂ layer)

After forming the metal-containing layer (NaCl layer, 1 nm), the substrate was placed in the following IAD Vacuum Coating Machine, and one SiO₂ layer (SiO₂ layer 7 nm) was formed on the formed metal-containing layer (NaCl layer, 1 nm).

On the metal-containing layer (NaCl layer, 1 nm), the SiO₂ layer (7 nm in thickness) was formed using the IAD Vacuum Coating Machine (BIS-1300DNN, manufactured by Shincron Co., Ltd.) under the following conditions.

<<Conditions in Chamber>>

Heating temperature: 30° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the hydrophilic layer: SiO₂ (Product Name: SiO₂, manufactured by Canon Optron, Inc.)

SiO₂ was loaded as the layer forming material in the first evaporation source of the IAD Vacuum Coating Machine, and the SiO₂ layer having a thickness of 7 nm was formed on the metal-containing layer (NaCl layer, 1 nm) by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

Thus, a unit consisting of a NaCl layer (1 nm)/SiO₂ layer (7 nm) was formed. This unit was repeatedly formed once more, and the third hydrophilic layer consisting of the two units was formed.

Functional Film 1 of Example 1 was obtained by the above processes.

In the production method of Functional Film 1, the reflectance adjustment layer, the photocatalytic layer, and the hydrophilic layer were formed using the same machine (BIS-1300DNN, manufactured by Shincron Co., Ltd.), and only the metal-containing layers having unevenness (the NaCl layer (5 nm) and the NaF layer (5 nm)) were formed using a different machine (BMC-800T, manufactured by Shincron Co., Ltd.).

The composition analysis of obtained Functional Film 1 of Example 1 was performed from measurement results using the following X-ray photoelectron spectroscopy (XPS) under the following conditions. The measurement results are shown in FIG. 12A and FIG. 12B. FIG. 12A shows the measurement results immediately after formation of the layer, and FIG. 12B shows the results that were measured after the layer had been left in a high temperature and high humidity environment of 85° C. and 85% RH for 300 hours.

Name of device: X-ray Photoelectron Spectrometer (XPS)

Model: Quantera SXM

Device manufacturer: ULVAC-PHI, Inc.

Measurement conditions: X-ray source: Monochromatized AlKα beam 25 W-15 kV

Degree of vacuum: 5.0×10⁻⁸ Pa

Analysis of depth profiles was performed by argon ion etching. Data were processed using analysis software MultiPak (manufactured by ULVAC-PHI, Inc.).

These results show that the presence of Al, Na, and F can be confirmed in the functional film in the sample immediately after layer formation and in the sample after high temperature and high humidity test.

### Example 2

### [Production of Functional Film 2]

A functional film with the layer configuration shown in FIG. 4A to FIG. 4C was produced. FIG. 4A is a schematic diagram of the entire layer configuration of the functional film of Example 2. FIG. 4B is a schematic diagram of the layer configuration of the base material 1, the reflectance adjustment layer 2, the photocatalytic layer 3, and the metal-fluorine-containing layer 4, 5 in FIG. 4A. FIG. 4C is a schematic diagram of the layer configuration of the metal-fluorine-containing layer 4, 5 and the hydrophilic layer 6 in FIG. 4A.

<Preparation of Base Material>

As the base material, a lens made of a glass material H-ZLAF55D (manufactured by CD GM) processed for an automotive lens was prepared in the same manner as the lens used in the production of Functional Film 1. This lens was cleaned for 600 seconds using a UV Ozone Cleaner (manufactured by Technovision, Inc.).

<Formation of Reflectance Adjustment Layer>

### (Formation of First Low Refractive Index Layer)

On the base material, a first low refractive index layer containing SiO₂ (SiO₂ layer, 17 nm) was formed using an IAD Vacuum Coating Machine (BIS-1300DNN, manufactured by Shincron Co., Ltd.) under the following conditions.

<<Conditions in Chamber>>

Heating temperature: 370° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the first low refractive index layer: SiO₂ (Product Name: SiO₂, manufactured by Canon Optron, Inc.)

The base material was installed in the IAD Vacuum Coating Machine, SiO₂ was loaded as the layer forming material in a first evaporation source, and the first low refractive index layer (SiO₂ layer) having a thickness of 17 nm was formed by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

Five first low refractive index layers described above were stacked. The five first low-refractive-index layers were formed in the same manner, except that only the topmost one was 18 nm in thickness.

The metal-fluorine-containing layers were formed at respective borders of the five first low-refractive-index layers (SiO₂ layers). That is, the first low-refractive-index layers and the metal-fluorine-containing layers were alternately stacked. The metal-fluorine-containing layers were formed by the following procedure.

<Formation of Metal-Fluorine-Containing Layer>

After the first low-refractive-index layer (SiO₂ layer, 17 nm) was formed, the metal-fluorine-containing layer (Na₅Al₃F₁₄, 1 nm) was formed under the same conditions as the SiO₂ layer except that the IAD was turned off, the layer forming material was Na₅Al₃F₁₄, and the deposition rate was 0.5 Å/sec.

(Formation of High Refractive Index Layer)

After the topmost first low-refractive-index layer (SiO₂ layer, 18 nm) was formed, a high refractive index layer (Ta₂O₅—TiO₂, 16 nm) was formed.

The high refractive index layer was formed in the same manner as the high refractive index layer (Ta₂O₅—TiO₂, 16 nm) in the production of Functional Film 1.

(Formation of Second Low Refractive Index Layer)

After the high refractive index layer (Ta₂O₅—TiO₂, 16 nm) was formed, a second low refractive index layer was formed by the following procedure.

On the high refractive index layer, the second low refractive index layer (SiO₂ layer, 14 nm) was formed continuously using the IAD Vacuum Coating Machine (BIS-1300DNN, manufactured by Shincron Co., Ltd.) under the following conditions.

<<Conditions in Chamber>>

Heating temperature: 370° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the second low refractive index layer: SiO₂ (Product Name: SiO₂, manufactured by Canon Optron, Inc.)

SiO₂ was loaded as the layer forming material in the first evaporation source of the IAD Vacuum Coating Machine, and the second low refractive index layer having a thickness of 14 nm was formed on the high refractive index layer by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

Three second low refractive index layers mentioned above were stacked. The three second low refractive index layers were formed in the same manner, except that only the topmost one was 15 nm in thickness.

The metal-fluorine-containing layers (Na₅Al₃F₁₄, 1 nm) were formed at respective borders of the three second low refractive index layers (SiO₂ layers). That is, the second low refractive index layers and the metal-fluorine-containing layers were alternately stacked. The metal-fluorine-containing layers were formed in the same manner as the metal-fluorine-containing layers (Na₅Al₃F₁₄, 1 nm) between the first low-refractive-index layers.

<Formation of Photocatalytic Layer>

On the topmost second low-refractive-index layer (SiO₂ layer, 15 nm), the photocatalytic layer (TiO₂ layer, 116 nm) was formed. The photocatalytic layer was formed in the same manner as the photocatalytic layer (TiO₂ layer, 116 nm) that is formed in the production of Functional Film 1.

<Formation of Hydrophilic Layer>

On the photocatalytic layer (TiO₂ layer, 116 nm), the hydrophilic layer was formed by the following procedure.

(SiO₂ Layer)

The substrate was placed in the following IAD Vacuum Coating Machine, and the hydrophilic layer (SiO₂ layer, 6 nm) was formed on the formed photocatalytic layer.

On the photocatalytic layer, the SiO₂ layer (6 nm in thickness) was formed using the IAD Vacuum Coating Machine (BIS-1300DNN, manufactured by Shincron Co., Ltd.) under the following conditions.

<<Conditions in Chamber>>

Heating temperature: 370° C.

Starting vacuum: 5.0×10⁻³ Pa

<<Evaporation Source of Layer Forming Material>>

Electron gun

<<IAD Ion Source>>

RF ion source NIS-175-3 (manufactured by Shincron Co., Ltd.)

Material for forming the hydrophilic layer: SiO₂ (Product Name: SiO₂, manufactured by Canon Optron,

Inc.)

SiO₂ was loaded as the layer forming material in the first evaporation source of the IAD Vacuum Coating Machine, and the SiO₂ layer having a thickness of 6 nm was formed on the photocatalytic layer by vapor deposition at a deposition rate of 3 Å/sec.

IAD was performed at an acceleration voltage of 1000 V, acceleration current of 1000 mA, suppressor voltage of 500 V, and neutralization current of 1500 mA, and the IAD introduction gas was 50 sccm of O₂, 0 sccm of Ar gas, and 10 sccm of neutral gas Ar.

Nine SiO₂ layers (6 nm) mentioned above were stacked.

The metal-fluorine-containing layers (Na₅Al₃F₁₄, 1 nm) were formed at respective borders of the nine SiO₂ layers. That is, the SiO₂ layers and the metal-fluorine-containing layers were alternately stacked. The metal-fluorine-containing layers were formed in the same manner as the metal-fluorine-containing layers (Na₅Al₃F₁₄, 1 nm) between the first low-refractive-index layers.

Functional film 2 of Example 2 was obtained by the above processes.

### Example 3

### [Production of Functional Film 3]

A functional film with the layer configuration shown in FIG. 5A to FIG. 5D was produced. FIG. 5A is a schematic diagram of the entire layer configuration of the functional film of Example 3. FIG. 5B is a schematic diagram of the layer configuration of the base material 1, the reflectance adjustment layer 2, and the photocatalytic layer 3 in FIG. 5A. FIG. 5C is a schematic diagram of the layer configuration of the fluorine-containing layer 4 in FIG. 5A. FIG. 5D is a schematic diagram of the layer configuration of the metal-containing and hydrophilic layer 5, 6 in FIG. 5A.

Functional Film 3 was formed in the same manner as the production of the above-mentioned Functional Film 1, except for the metal-containing and hydrophilic layer 5, 6 shown below.

<Formation of Metal-Containing and Hydrophilic Layer>

On the CaF₂ layer (2 nm) of the fluorine-containing layer, Na-containing SiO₂ (Product name: EXCELPURE S01, manufactured by CENTRAL AUTOMOTIVE PRODUCTS LTD.) was applied, and the Na-containing SiO₂ layer (metal-containing and hydrophilic layer) having a thickness of 90 nm was formed.

### Example 4

### [Production of Functional Film 4]

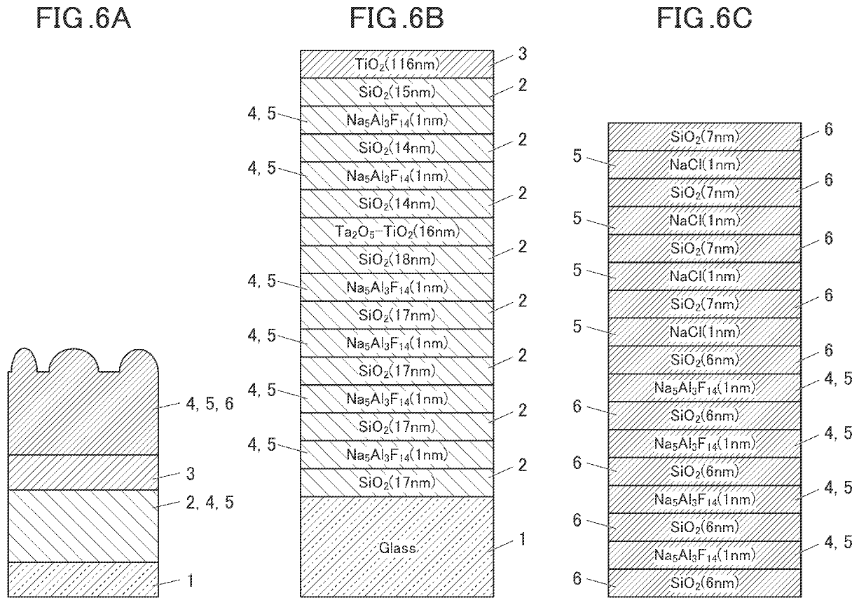

A functional film with the layer configuration shown in FIG. 6A to FIG. 6C was produced. FIG. 6A is a schematic diagram of the entire layer configuration of the functional film of Example 4. FIG. 6B is a schematic diagram of the layer configuration of the base material 1, the reflectance adjustment layer 2, the photocatalytic layer 3, and the metal-fluorine-containing layer 4, 5 in FIG. 6A. FIG. 6C is a schematic diagram of the layer configuration of the metal-fluorine-containing layer 4, 5, the hydrophilic layer 6, and the metal-containing layer 5 in FIG. 6A.

Functional Film 4 was formed in the same manner as the production of the above-mentioned Functional Film 2, except for the hydrophilic layer shown below.

<Formation of Hydrophilic Layer>

The hydrophilic layers of the above Functional Film 2 were the metal-fluorine-containing layers (Na₅Al₃F₁₄, 1 nm) formed at respective borders of the nine SiO₂ layers. However, in Functional Film 3, the metal-fluorine-containing layers (Na₅Al₃F₁₄, 1 nm) were formed at respective borders of the lower four SiO₂ layers (6 nm), and the metal-containing layers (NaCl) were formed at respective borders of the upper four SiO₂ layers (7 nm). The eight SiO₂ layers and the four metal-fluorine-containing layers (Na₅Al₃F₁₄, 1 nm) were formed in the same manner as the above Functional Film 2. The four metal-containing layers (NaCl, 1 nm) were formed in the same manner as the third hydrophilic layer of Functional Film 1, except the temperature was set to 370° C.

### Example 5

### [Production of Functional Film 5]

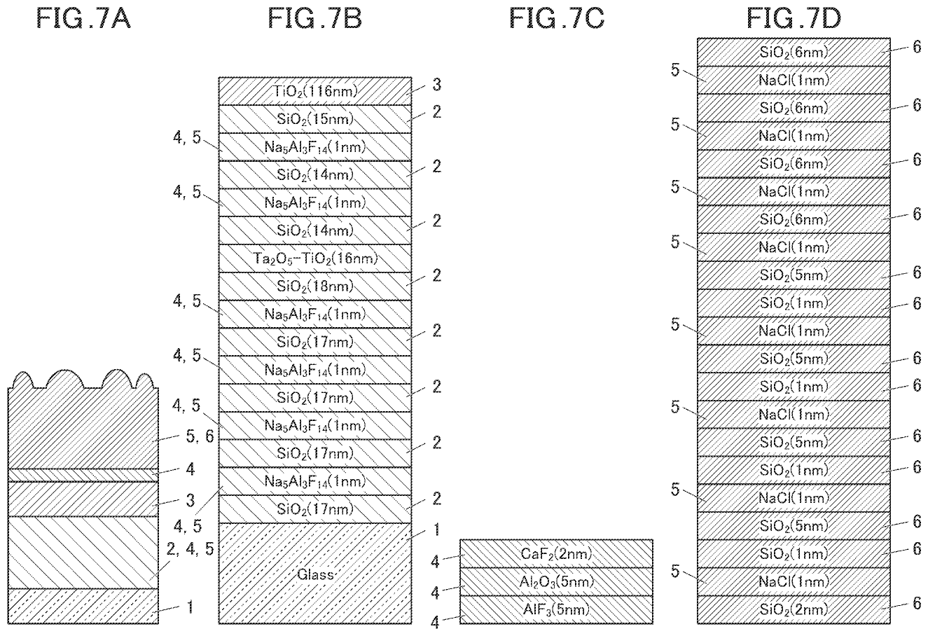

A functional film with the layer configuration shown in FIG. 7A to FIG. 7D was produced. FIG. 7A is a schematic diagram of the entire layer configuration of the functional film of Example 5. FIG. 7B is a schematic diagram of the layer configuration of the base material 1, the reflectance adjustment layer 2, the photocatalytic layer 3, and the metal-fluorine-containing layer 4, 5 in FIG. 7A. FIG. 7C is a schematic diagram of the layer configuration of the fluorine-containing layer 4 in FIG. 7A. FIG. 7D is a schematic diagram of the layer configuration of the metal-containing layer 5 and the hydrophilic layer 6 in FIG. 7A.

Functional Film 5 was formed in the same manner as the production of the above-mentioned Functional Film 2, except that, the hydrophilic layer formed after formation of the fluorine-containing layer (AlF₃ layer/Al₂O₃ layer/CaF₂ layer) on the photocatalytic layer (TiO₂ layer) was changed to a configuration shown in FIG. 7D.

Specifically, one SiO₂ layer (2 nm) was formed on the CaF₂ layer, and then a unit of NaCl layer (1 nm)/SiO₂ layer (1 nm)/SiO₂ layer (5 nm) was formed four times repeatedly. After that, a unit of NaCl layer (1 nm)/SiO₂ layer (6 nm) was further formed four times repeatedly.

The SiO₂ layers were formed to be the respective desired thicknesses by the same procedure as the SiO₂ layer of Functional Film 1 except that the heating temperature was changed to 370° C. That is, the SiO₂ layer of 1 nm thickness was formed with the IAD turned on, and the SiO₂ layers of 5 nm and 6 nm thickness were formed with IAD turned off. The NaCl layers were also formed to the desired thickness by the same procedure as the NaCl layer of Functional Film 4.

### Example 6

### [Production of Functional Film 6]

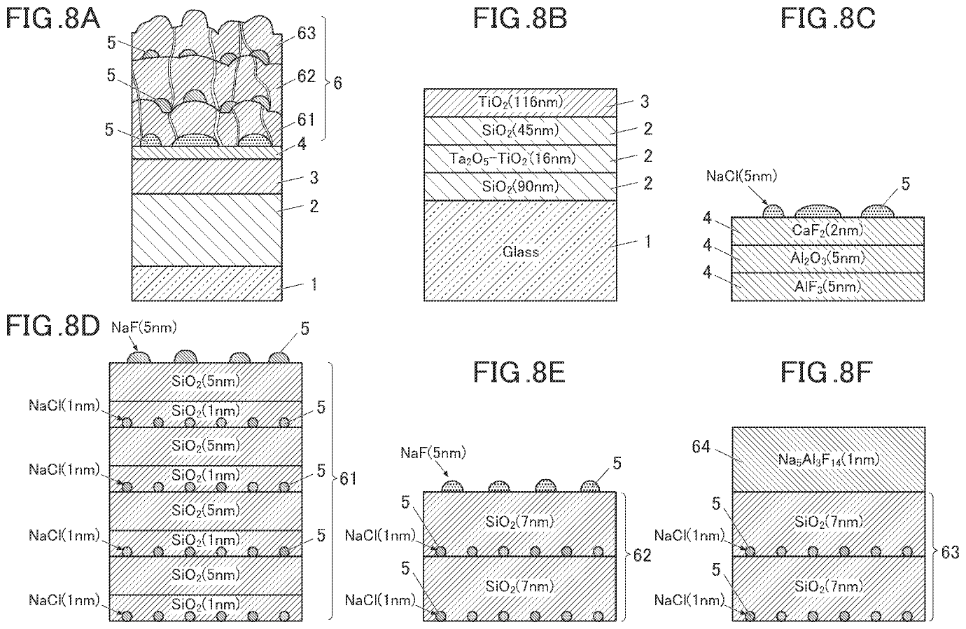

A functional film with the layer configuration shown in FIG. 8A to FIG. 8F was produced. FIG. 8A is a schematic diagram of the entire layer configuration of the functional film of Example 6. FIG. 8B is a schematic diagram of the layer configuration of the base material 1, the reflectance adjustment layer 2, and the photocatalytic layer 3 in FIG. 8A. FIG. 8C is a schematic diagram of the layer configuration of the fluorine-containing layer 4 and the metal-containing layer 5 having unevenness in FIG. 8A. FIG. 8D to FIG. 8F are schematic diagrams of the layer configurations of the first to third hydrophilic layers 61 to 63, respectively, with the metal-containing layers 5 having unevenness and the like in FIG. 8A.

Functional Film 6 was formed in the same manner as the production of above-mentioned Functional Film 1, except that a Na₅Al₁₃F₁₄ layer (1 nm) was further formed on the third hydrophilic layer 63 as a salt water resistant layer 64.

The salt water resistant layer was formed in the same manner as the Na₅Al₃F₁₄ layer (1 nm) of the functional film 2 except that the heating temperature was 30° C.

### Example 7

### [Production of Functional Film 7]

A functional film with the layer configuration shown in FIG. 9A to FIG. 9C was produced. FIG. 9A is a schematic diagram of the entire layer configuration of the functional film of Example 7. FIG. 9B is a schematic diagram of the layer configuration of the base material 1, the reflectance adjustment layer 2, the photocatalytic layer 3, and the metal-fluorine-containing layer 4, 5 in FIG. 9A. FIG. 9C is a schematic diagram of the layer configuration of the metal-fluorine-containing layer 4, 5 and the hydrophilic layer 6 in FIG. 9A.

Functional Film 7 was formed in the same manner as the production of Functional Film 2, except that all the Na₅Al₃F₁₄ layers (1 nm) were changed to Na₃AlF₆ layers (1 nm).

The Na₃AlF₆ layers (1 nm) were formed in the same manner as the Na₅Al₃F₁₄ layers (1 nm) of the functional film 2 with IAD turned off, except that Na₃AlF₆ was used as the layer forming material.

### Example 8

### [Production of Functional Film 8]

Functional Film 8 was formed in the same manner as the production of Functional Film 1, except that the fluorine-containing layer (AlF₃ layer/Al₂O₃ layer/CaF₂ layer) was changed to a single layer configuration of MgF₂ layer (45 nm) as shown in TABLE I below, and the layer forming material was changed to MgF₂.

### Example 9

### [Production of Functional Film 9]

Functional Film 9 was formed in the same manner as the production of Functional Film 1, except that the fluorine-containing layer (AlF₃ layer/Al₂O₃ layer/CaF₂ layer) was changed to the layer configuration shown in TABLE I below.

Specifically, the fluorine-containing layer was changed to have a two layer configuration of AlF₃ layer (5 nm)/Al₂O₃ layer (5 nm).

### Example 10

### [Production of Functional Film 10]

Functional Film 10 was formed in the same manner as the production of Functional Film 1, except that the fluorine-containing layer (AlF₃ layer/Al₂O₃ layer/CaF₂ layer) was changed to the layer configuration shown in TABLE I below.

Specifically, the fluorine-containing layer was changed to have a single layer configuration of AlF₃ layer (5 nm).

### Example 11

### [Production of Functional Film 11]

Functional Film 11 was formed in the same manner as the production of Functional Film 1, except that the NaCl layers were not formed at the border of the SiO₂ layers in the first to third hydrophilic layers.

### Examples 12 to 18

### [Production of Functional Films 12 to 18]

Functional films 12 to 18 were formed in the same manner as the production of Functional Film 1, except that the base material was changed as shown in TABLE I below.

The base materials shown in TABLE I below are detailed as follows.

“H-ZLAF55D lens”: a lens made of the glass material H-ZLAF55D (manufactured by CDGM GLASS CO., LTD.) processed for automotive lens

“tafD glass”: a substrate made of the glass material H-ZLAF55D (manufactured by CDGM GLASS CO., LTD.) processed into a plate shape

“BK7 Glass”: a plate substrate of the glass material BK7 (manufactured by Piezo Parts Co., Ltd.)

“Super White plate glass”: a plate substrate of the glass material B270i (manufactured by Piezo Parts Co., Ltd.)

“PET film”: a resin film of the KB FILM 125G1SBF (manufactured by KIMOTO Co., Ltd.)

“Methacrylic resin”: a substrate made of methacrylic resin molded into a sheet shape

“Chalcogenide”: a substrate made of chalcogenide processed into a plate shape

“Cr”: a substrate made of Cr metal processed into a plate shape

The “radius of curvature” in TABLE I means the radius of curvature of the lens. The radius of curvature of the plate substrate is indicated as “∞ (infinite)” in TABLE I.

The content of Na (sodium) in the base material was measured using the X-ray photoelectron spectroscopy (XPS) under the same conditions as those in the composition analysis of Functional Film 1 of Example 1. The measured content is shown in the table.

### Comparative Example 1

### [Production of Functional Film 19]

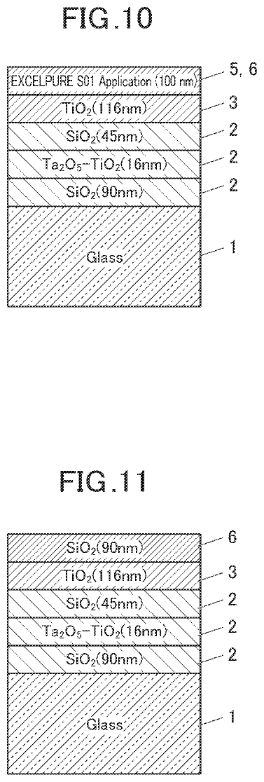

A functional film having the layer configuration shown in FIG. 10 was produced. FIG. 10 is a schematic diagram of the entire layer configuration of the functional film of Comparative Example 1.

Functional Film 19 was formed in the same manner as the production of Functional Film 1, until the photocatalytic layer (TiO₂ layer, 116 nm) was formed. After that, on the photocatalytic layer, Na-containing SiO₂ (Product name: EXCELPURE S01, manufactured by CENTRAL AUTOMOTIVE PRODUCTS LTD.) used in the production of Functional Film 3 was applied, and the Na-containing SiO₂ layer (metal-containing and hydrophilic layer) having a thickness of 100 nm was formed.

### Comparative Example 2

### [Production of Functional Film 20]

A functional film having the layer configuration shown in FIG. 11 was produced. FIG. 11 is a schematic diagram of the entire layer configuration of the functional film of Comparative Example 2.

Functional Film 20 was formed in the same manner as the production of Functional Film 1, until the photocatalytic layer (TiO₂ layer, 116 nm) was formed. After that, on the photocatalytic layer, a SiO₂ layer (hydrophilic layer) having a thickness of 90 nm was formed in the same manner as the hydrophilic layer (SiO₂ layer, 5 nm) of Functional Film 1.

### Comparative Example 3

### [Production of Functional Film 21]

Functional Film 21 was produced in the same manner as the production of Functional Film 20, except that the base material was changed as shown in TABLE I below.

In each of the functional films obtained above, the average roughness Ra of the bumps, the maximum height of the bumps, and the average diameter of the bumps were calculated by the following method and shown in TABLE II below.

<Average Roughness Ra of Bumps>

The arithmetic average roughness Ra of the bumps was obtained by measuring roughness values at 10 or more bumps using an atomic force microscope (L-Trace, manufactured by Hitachi High-Tech Science Corporation) and calculating their average, as described above.

<Maximum Height of Bumps>

The maximum height of the bumps was obtained by measuring height values of 10 or more bumps using an atomic force microscope (L-Trace, manufactured by Hitachi High-Tech Science Corporation) and determining the maximum value of them.

<Average Diameter of Bumps>

The average diameter of bumps was obtained by measuring diameter values of 10 or more bumps using an electron microscope (S-4800, manufactured by Hitachi High-Tech Science Corporation) and calculating their average.

<Presence or Absence of Diffracted Light>

The presence or absence of the diffracted light was checked by placing each of the functional film obtained as described above between the helium-neon laser source and a screen, irradiating the screen with light through the functional film, and then visually checking the light on the screen.

[Evaluation]

### <Contact Angle Under High Temperature and Dry Environment for 100 Hours>

The functional films were each left in a high temperature (85° C.) and dry environment for 100 hours. After that, 10 μL of pure water was dropped onto the surface of the functional film in an environment of 23° C. and 50% RH. The static contact angle measured 5 seconds after the drop using the contact angle measurement device G-1 (manufactured by ERMA Inc.) was defined as the contact angle A1.

The measured contact angle A1 was then ranked according to the following criteria.

The 85° C. and dry environment was achieved by setting the temperature to 85° C. using a compact high-temperature chamber ST-120 (manufactured by ESPEC CORP.).

(Criteria)

AA: Contact angle A1 is 10° or less.

BB: Contact angle A1 is more than 10° and 30° or less.

CC: Contact angle A1 is more than 30° and 60° or less.

DD: Contact angle A1 is more than 60°.

<Contact Angle Under High Temperature and High Humidity Environment for 100 Hours>

The functional films were each left in a high temperature and high humidity (85° C., 85% RH) environment for 100 hours. Then, 10 μL of pure water was dropped onto the surface of the functional film in an environment of 23° C. and 50% RH. The static contact angle measured five seconds after the drop using the contact angle measurement device G-1 (manufactured by ERMA Inc.) was defined as the contact angle B 1.

The measured contact angle B1 was then ranked according to the following criteria.

(Criteria)

AA: Contact angle B1 is 10° or less.

BB: Contact angle B1 is more than 10° and 30° or less.

CC: Contact angle B1 is more than 30° and 60° or less.

DD: Contact angle B1 is more than 60°.

<Contact Angle after Rubbing with Scourer (0.1 kg, 100 Times)>

The surface of each of the functional films was rubbed with the scourer (Kamenoko Tawashi) 100 times back and forth with a load of 0.1 kg. Then, 10 μL of pure water was dropped onto the surface of the functional film under an environment of 23° C. and 50% RH. The static contact angle measured 5 seconds after the drop using the contact angle measurement device G-1 (manufactured by ERMA Inc.) was defined as the contact angle C1.

The measured contact angle C1 was then ranked according to the following criteria.

(Criteria)

AA: Contact angle C1 is 10° or less.

BB: Contact angle C1 is more than 10° and 30° or less.

CC: Contact angle C1 is more than 30° and 60° or less.

DD: Contact angle C1 is more than 60°.

<Visible Scratch after Rubbing with Scourer (0.1 kg, 100 Times)>

The surface of each of the functional films was rubbed with the scourer (Kamenoko Tawashi) 100 times back and forth with a load of 0.1 kg. Then, five areas suspected to be scratches and five areas without scratches were determined through observation of the surface of the functional film using an optical microscope SZX10 (manufactured by Olympus Corporation) at a magnification of 10 times or more. The reflectance of the five areas suspected to be scratches and the reflectance of the five areas without scratches were each measured in the wavelength range of 420 to 670 nm using a micro-area spectral reflectance measurement device USPM-RU (manufactured by Olympus Corporation). The difference between the average reflectance of the areas suspected to be scratches and the average reflectance of the areas without scratches was then ranked according to the following criteria.

(Criteria)

AA: Difference between average reflectance is less than 1%.

BB: Difference between average reflectance is 1% or more and less than 1.5%.

CC: Difference between average reflectance is 1.5% or more and less than 2%.

DD: Difference between average reflectance is 2% or more.

<Contact Angle Under High Temperature and Dry Environment for 1000 Hours>

Contact angle A2 was measured in the same manner as the evaluation method of “Contact angle under High Temperature and Dry Environment for 100 Hours,” except that the 100 hours was changed to 1000 hours.

Then, the measured contact angle A2 was also ranked according to the criteria of “Contact angle under High Temperature and Dry Environment for 100 Hours.”

<Contact Angle Under High Temperature and High Humidity Environment for 1000 Hours>

Contact angle B2 was measured in the same manner as the evaluation method of “Contact angle under High Temperature and High Humidity Environment for 100 Hours,” except that the 100 hours was changed to 1000 hours.

Then, the measured contact angle B2 was also ranked according to the criteria of “Contact angle under High Temperature and High Humidity Environment for 100 Hours.”

<Contact Angle after Rubbing with Scourer (1 kg, 500 Times)>

Contact angle C2 was measured in the same manner as the evaluation method of “Contact angle after Rubbing with Scourer (0.1 kg, 100 times),” except that the functional films was rubbed with the scourer 500 times back and forth with a load of 1 kg.

Then, the measured contact angle C2 was also ranked according to the criteria of “Contact angle after Rubbing with Scourer (0.1 kg, 100 times).”

<Visible Scratch after Rubbing with Scourer (1 kg, 500 Times)>

The presence or absence of visible scratches on the surface of the functional film was obtained in the same manner as the evaluation method of “Visible Scratch after Rubbing with Scourer (0.1 kg, 100 times),” except that the functional films was rubbed with the scourer 500 times back and forth with a load of 1 kg, and ranked according to the criteria of “Contact angle after Rubbing with Scourer (0.1 kg, 100 times).”

TABLE 1

| | Base Material | | | | | | |
|---|---|---|---|---|---|---|---|
| | | Radius | Content | | | | |
| | | of | of | | | | |
| Functional | | Curvature | Na | | | | |
| Film No. | Type | [ nm] | [%] | Fluorine-Containing Layer | | | |
| 1 | H-ZLAF55D lens | 12 | 0 | AlF₃(5 nm) | Al₂O₃ (5 nm) | CaF₂ (2 nm) | — |
| 2 | H-ZLAF55D lens | 12 | 0 | Na₅Al₃F₁₄ | — | — | — |
| 3 | H-ZLAF55D lens | 12 | 0 | AlF₃ (5 nm) | Al₂O₃ (5 nm) | CaF₂ (2 nm) | — |
| 4 | H-ZLAF55D lens | 12 | 0 | Na₅Al₃F₁₄ | — | — | — |
| 5 | H-ZLAF55D lens | 12 | 0 | Na₅Al₃F₁₄ | AlF₃ (5 nm) | Al₂O₃ (5 nm) | CaF₂ (2 nm) |
| 6 | H-ZLAF55D lens | 12 | 0 | AlF₃ (5 nm) | Al₂O₃ (5 nm) | CaF₂ (2 nm) | — |
| 7 | H-ZLAF55D lens | 12 | 0 | Na₃AlF₆ | — | — | — |
| 8 | H-ZLAF55D lens | 12 | 0 | MgF₂ (45 nm) | — | — | — |
| 9 | H-ZLAF55D lens | 12 | 0 | AlF₃ (5 nm) | Al₂O₃ (5 nm) | — | — |
| 10 | H-ZLAF55D lens | 12 | 0 | AlF₃ (5 nm) | — | — | — |
| 11 | H-ZLAF55D lens | 12 | 0 | AlF₃ (5 nm) | Al₂O₃ (5 nm) | CaF₂ (2 nm) | — |
| 12 | tafD Glass | ∞ | 0 | AlF₃ (5 nm) | Al₂O₃ (5 nm) | CaF₂ (2 nm) | — |
| 13 | BK7 Glass | ∞ | 2.5 | AlF₃ (5 nm) | Al₂O₃ (5 nm) | CaF₂ (2 nm) | — |
| 14 | Super White Glass | ∞ | 3.5 | AlF₃ (5 nm) | Al₂O₃ (5 nm) | CaF₂ (2 nm) | — |
| 15 | PET film | ∞ | 0 | AlF₃ (5 nm) | Al₂O₃ (5 nm) | CaF₂ (2 nm) | — |
| 16 | Methacrylic Resin | ∞ | 0 | AlF₃ (5 nm) | Al₂O₃ (5 nm) | CaF₂ (2 nm) | — |
| 17 | Chalcogenide | ∞ | 0 | AlF₃ (5 nm) | Al₂O₃ (5 nm) | CaF₂ (2 nm) | — |
| 18 | Cr | ∞ | 0 | AlF₃ (5 nm) | Al₂O₃ (5 nm) | CaF₂ (2 nm) | — |
| 19 | H-ZLAF55D lens | 12 | 0 | — | — | — | — |
| 20 | H-ZLAF55D lens | 12 | 0 | — | — | — | — |
| 21 | tafD Glass | ∞ | 0 | — | — | — | — |

| | | Hydrophilic Layer | | | |
|---|---|---|---|---|---|
| | | First | Second | Third | |
| Functional | Metal-Containing | Hydrophilic | Hydrophilic | Hydrophilic | |
| Film No. | Layer | Layer | Layer | Layer | Remarks |
| 1 | NaCl, NaF | NaCl, SiO₂ | NaCl, SiO₂ | NaCl, SiO₂ | Inv. 1 |
| 2 | Na₅Al₃F₁₄ | Na₃Al₃F₁₄, SiO₂ | — | — | Inv. 2 |
| 3 | Na-containing SiO₂ | Na-containing SiO₂ | — | — | Inv. 3 |
| | Application | Application | | | |
| 4 | Na₅Al₃F₁₄ | Na₅Al₃F₁₄, NaCl, SiO₂ | — | — | Inv. 4 |
| 5 | Na₅Al₃F₁₄ | NaCl, SiO₂ | — | — | Inv. 5 |
| 6 | NaCl, NaF | NaCl, SiO₂ | NaCl, SiO₂ | NaCl, SiO₂ | Inv. 6 |
| 7 | Na₃AlF₆ | Na₅Al₃F₁₄, SiO₂ | — | — | Inv. 7 |
| 8 | NaCl, NaF | NaCl, SiO₂ | NaCl, SiO₂ | NaCl, SiO₂ | Inv. 8 |
| 9 | NaCl, NaF | NaCl, SiO₂ | NaCl, SiO₂ | NaCl, SiO₂ | Inv. 9 |
| 10 | NaCl, NaF | NaCl, SiO₂ | NaCl, SiO₂ | NaCl, SiO₂ | Inv. 10 |
| 11 | NaCl, NaF | SiO₂ | SiO₂ | SiO₂ | Inv. 11 |
| 12 | NaCl, NaF | NaCl, SiO₂ | NaCl, SiO₂ | NaCl, SiO₂ | Inv. 12 |
| 13 | NaCl, NaF | NaCl, SiO₂ | NaCl, SiO₂ | NaCl, SiO₂ | Inv. 13 |
| 14 | NaCl, NaF | NaCl, SiO₂ | NaCl, SiO₂ | NaCl, SiO₂ | Inv. 14 |
| 15 | NaCl, NaF | NaCl, SiO₂ | NaCl, SiO₂ | NaCl, SiO₂ | Inv. 15 |
| 16 | NaCl, NaF | NaCl, SiO₂ | NaCl, SiO₂ | NaCl, SiO₂ | Inv. 16 |
| 17 | NaCl, NaF | NaCl, SiO₂ | NaCl, SiO₂ | NaCl, SiO₂ | Inv. 17 |
| 18 | NaCl, NaF | NaCl, SiO₂ | NaCl, SiO₂ | NaCl, SiO₂ | Inv. 18 |
| 19 | Na-containing SiO₂ | Na-containing SiO₂ | — | — | Comp. 1 |
| | Application | Application | | | |
| 20 | — | SiO₂ | — | — | Comp. 2 |
| 21 | — | SiO₂ | — | — | Comp. 3 |

TABLE II

| | | | | | Contact angle under | Contact angle |
|---|---|---|---|---|---|---|
| | Average | Maximum | Average | | High Temperature | after 100 hours at |
| | Roughness | Height | Diameter | | and Dry Environment | High Temperature |
| Functional | of Bump | of Bump | of Bump | Diffracted | for 100 hours | and High Humidity |
| Film No. | [nm] | [nm] | [mm] | Light | [°] | [°] |
| 1 | 18 | 147 | 40 | None | 0 | 0 |
| 2 | 17 | 132 | 34 | None | 0 | 0 |
| 3 | 6 | 59 | 38 | None | 0 | 3 |
| 4 | 16 | 118 | 36 | None | 0 | 0 |
| 5 | 18 | 152 | 40 | None | 0 | 0 |
| 6 | 17 | 142 | 39 | None | 0 | 0 |
| 7 | 11 | 82 | 29 | None | 0 | 0 |
| 8 | 15 | 135 | 33 | None | 0 | 28 |
| 9 | 17 | 128 | 35 | None | 0 | 0 |
| 10 | 17 | 140 | 32 | None | 0 | 0 |
| 11 | 2 | 19 | 23 | None | 11 | 26 |
| 12 | 15 | 123 | 29 | None | 0 | 1 |
| 13 | 16 | 129 | 30 | None | 1 | 1 |
| 14 | 17 | 142 | 38 | None | 1 | 0 |
| 15 | 14 | 120 | 29 | None | 1 | 1 |
| 16 | 18 | 132 | 35 | None | 1 | 2 |
| 17 | 1 | 139 | 38 | None | 1 | 2 |
| 18 | 18 | 152 | 48 | None | 1 | 2 |
| 19 | 6 | 59 | 38 | None | 0 | 34 |
| 20 | 0.6 | 16 | 10 | None | 33 | 4 |
| 21 | 0.6 | 16 | 10 | None | 23 | 29 |

| | | | Contact angle | Contact angle | | | |
|---|---|---|---|---|---|---|---|
| | | | Under High | after 1000 | Contact angle | | |
| | Contact angle | Visible Scratch | Temperature and | hours at High | after Rubbing | Visible Scratch | |
| | after Rubbing | after Rubbing | Dry Environment | Temperature and | with a Scourer | after Rubbing | |
| Functional | with a Scourer | with Scourer | for 1000 hours | High Humidity | [°] | with Scourer | |
| Film No. | (0.1 kg. 10 times) | (0.1 kg. 100 times) | [°] | [°] | (1 kg. 500 times) | (1 kg. 500 times) | Remarks |
| 1 | 0 | AA | 0 | 0 | 0 | AA | Inv. 1 |
| 2 | 0 | AA | 0 | 7 | 0 | AA | Inv. 2 |
| 3 | 26 | CC | 0 | 22 | 45 | CC | Inv. 3 |
| 4 | 0 | AA | 0 | 0 | 0 | AA | Inv. 4 |
| 5 | 0 | AA | 0 | 0 | 0 | AA | Inv. 5 |
| 6 | 0 | AA | 0 | 0 | 0 | AA | Inv. 6 |
| 7 | 0 | AA | 0 | 0 | 0 | AA | Inv. 7 |
| 8 | 2 | AA | 0 | 40 | 5 | AA | Inv. 8 |
| 9 | 0 | AA | 0 | 0 | 0 | AA | Inv. 9 |
| 10 | 0 | AA | 0 | 0 | 0 | AA | Inv. 10 |
| 11 | 5 | AA | 30 | 33 | 7 | AA | Inv. 11 |
| 12 | 4 | AA | 1 | 5 | 1 | AA | Inv. 12 |
| 13 | 4 | AA | 2 | 3 | 5 | AA | Inv. 13 |
| 14 | 5 | AA | 4 | 2 | 4 | AA | Inv. 14 |
| 15 | 3 | AA | 2 | 5 | 5 | AA | Inv. 15 |
| 16 | 2 | AA | 3 | 9 | 5 | AA | Inv. 16 |
| 17 | 2 | AA | 2 | 4 | 4 | AA | Inv. 17 |
| 8 | 3 | AA | 1 | 2 | 3 | AA | Inv. 18 |
| 19 | 44 | CC | 0 | 58 | 55 | CC | Comp. 1 |
| 20 | 18 | AA | 50 | 68 | 25 | AA | Comp. 2 |
| 21 | 11 | AA | 42 | 50 | 16 | AA | Comp. 3 |

As can be seen from the above results, even when the base material does not contain hydrophilic components, the functional films of the present invention have smaller contact angles in a high temperature and high temperature and high humidity environments and have better functional film characteristics and rub resistance than the functional films of the comparative examples.

Although embodiments of the present invention have been described and illustrated in detail, the disclosed embodiments are made for purposes of illustration and example only and not limitation. The scope of the present invention should be interpreted by terms of the appended claims.

1. A functional film that has a hydrophilic property or an antifog property and that is formed on abase material, comprising:
a fluorine-containing layer that contains fluorine.

2. The functional film according to claim 1, further comprising:
a metal-containing layer that contains an alkali metal or an alkaline earth metal.

3. The functional film according to claim 2,
wherein the metal-containing layer contains sodium.

4. The functional film according to claim 1,
wherein the fluorine-containing layer further contains aluminum.

5. The functional film according to claim 1, further comprising:
a layer that contains SiO₂.

6. The functional film according to claim 1,
wherein a part of the fluorine-containing layer contains at least one of or constituent elements of at least one of AlF₃, Al₂O₃, CaF₂, NaF, Na₅Al₃F₁₄, and Na₃AlF₆.

7. The functional film according to claim 1,
wherein the base material contains an alkali metal or an alkaline earth metal, and
wherein a content of the alkali metal or the alkaline earth metal in the base material is 3% by mass or less.

8. The functional film according to claim 1,
wherein a surface of the functional film has a fine uneven structure, and
wherein the fine uneven structure includes bumps and dents whose mutual positional relationship and shape are random and have no regularity in terms of identity or periodicity and does not generate diffracted light.

9. The functional film according to claim 8,
wherein an arithmetic average roughness Ra of the bumps is in a range of 0.5 to 50 nm,
wherein a maximum height of the bumps is in a range of 10 to 300 nm, and
wherein an average diameter of the bumps is in a range of 10 to 500 nm.

10. The functional film according to claim 8,
wherein the fine uneven structure has a gap between bumps and dents adjacent to each other, the gap having a size that allows active chemical species generated by a photocatalyst reaction to pass through the gap.

11. The functional film according to claim 8, further comprising:
a photocatalytic layer between the base material and the fine uneven structure.

12. The functional film according to claim 1,
wherein a contact angle of a surface of the functional film after 100 hours of storage in a 85° C. and 85% RH environment is 30° or less.

13. The functional film according to claim 1,
wherein, upon a rub resistance test in which a surface of the functional film is rubbed with a palm fiber scourer 100 times back and forth with a load of 0.1 kg, a contact angle of the surface is 30° or less.

14. The functional film according to claim 1,
wherein a contact angle of a surface of the functional film after 100 hours of storage in a 85° C. and dry environment is 30° or less.

15. The functional film according to claim 1,
wherein, upon a rub resistance test in which a surface of the functional film is rubbed with a palm fiber scourer 100 times back and forth with a load of 0.1 kg, no visible scratch appears on the surface.

16. A production method of the functional film according to claim 1, comprising:
forming of the fluorine-containing layer on the base material.

17. The production method according to claim 16, further comprising:
forming of a metal-containing layer that contains an alkali metal or an alkaline earth metal by a dry process.

18. The production method according to claim 17,
wherein the forming of the metal-containing layer includes exposure to an environment containing moisture.

19. The production method according to claim 17,
wherein the forming of the metal-containing layer includes forming of an uneven structure.

20. The production method according to claim 17, further comprising:
after the forming of the metal-containing layer, forming of a layer containing SiO₂ on the metal-containing layer by a dry process.

21. The production method according to claim 16,
wherein, in the forming of the fluorine-containing layer, the fluorine-containing layer includes fluorine-containing layers that are granular layers of less than 10 nm and alternately stacked with layers other than the fluorine-containing layers, such that a fine uneven structure is formed on a surface of the functional film.

22. The production method according to claim 16,
wherein, in the forming of the fluorine-containing layer, the fluorine-containing layer is formed at a temperature of 200° C. or higher.

23. The production method according to claim 16,
wherein all layers of the functional film are formed by a dry process.

24. The production method according to claim 16,
wherein at least one layer of the functional film is formed by a wet process.
